(19) United States
(12) Patent Application Publication
(10) Pub. No.: US 2026/0074980 A1
(43) Pub. Date: Mar. 12, 2026

(54) SENDER AND RECEIVER, AN OPERATION METHOD THEREOF, AND AN ELECTRONIC DEVICE INCLUDING THE SAME

(71) Applicant: SAMSUNG ELECTRONICS CO., LTD., SUWON-SI (KR)

(72) Inventors: Kangtae CHO, Suwon-si (KR); WOOIL KIM, Suwon-si (KR)

(21) Appl. No.: 19/206,173

(22) Filed: May 13, 2025

(30) Foreign Application Priority Data
Sep. 12, 2024 (KR) 10-2024-0124973

(51) Int. Cl. H04L 43/10; H03K 21/08

(52) U.S. Cl. CPC H04L 43/10; H03K 21/08

(57) ABSTRACT

An electronic system including: a first electronic device including a sender that is configured to transmit data; and a second electronic device including a receiver that is configured to receive the data, wherein the sender is configured to: transmit a clock signal, an enable signal, and a heartbeat signal to the receiver; update a sending count value in response to the clock signal and the enable signal; and generate the heartbeat signal when the sending count value is a first value, and wherein the receiver is configured to: update a receiving count value in response to the clock signal and the enable signal; and generate an error signal when the receiving count value does not have the first value upon receipt of the heartbeat signal.

### CROSS-REFERENCE TO RELATED APPLICATION

This application claims priority under 35 U.S. C. § 119 to Korean Patent Application No. 10-2024-0124973 filed on Sep. 12, 2024, in the Korean Intellectual Property Office, the disclosure of which is incorporated by reference herein in its entirety.

### TECHNICAL FIELD

Embodiments of the present disclosure relate to a semiconductor device, specifically a sender and a receiver, an operating method thereof, and an electronic device including the same.

### DISCUSSION OF RELATED ART

An electronic device may include multiple processing units and various types of system-on-chips (SoCs) to perform specific functions. Communication between a processing unit and a SoC, or between SoCs, may be synchronized using a clock signal with data being detected in response to the clock signal.

Various error detection methods may be used in such communications. For example, data may be encoded with a parity bit. However, if the clock signal is lost, the processing unit or the SoC may fail to detects its absence, potentially resulting in undetected and lost data. Therefore, a device and method are need to indicate a communication error when the clock signal is lost.

### SUMMARY

Embodiments of the present disclosure provide a sender and receiver capable of detecting errors and clock signal loss, an operating method thereof, and an electronic device including the same.

According to an embodiment of the present disclosure, there is provided an electronic system including: a first electronic device including a sender that is configured to transmit data; and a second electronic device including a receiver that is configured to receive the data, wherein the sender is configured to: transmit a clock signal, an enable signal, and a heartbeat signal to the receiver; update a sending count value in response to the clock signal and the enable signal; and generate the heartbeat signal when the sending count value is a first value, and wherein the receiver is configured to: update a receiving count value in response to the clock signal and the enable signal; and generate an error signal when the receiving count value does not have the first value upon receipt of the heartbeat signal.

According to an embodiment of the present disclosure, there is provided a receiver for receiving data, the receiver including: a receiver count circuit configured to receive a clock signal and an enable signal and to update a receiving count value; and an error detection circuit configured to receive a heartbeat signal and the receiving count value, and to generate an error signal in response to the clock signal, wherein the error detection circuit generates the error signal when the receiving count value is not equal to a first value upon receipt of the heartbeat signal.

According to an embodiment of the present disclosure, there is provided an operating method of a receiver for receiving data, the method including: receiving a clock signal, an enable signal, and the data; updating a receiving count value in response to the enable signal and the clock signal; receiving a heartbeat signal, and determining whether the receiving count value is a first value, when the heartbeat signal is received; and generating an error signal when the receiving count value is not the first value.

### BRIEF DESCRIPTION OF THE DRAWINGS

The above and other features of the present disclosure will become apparent by describing in detail embodiments thereof with reference to the accompanying drawings.

FIG. 1 is a block diagram showing an electronic system, according to an embodiment of the present disclosure.

FIG. 2 is a block diagram showing an example of a sender and a receiver of FIG. 1, according to an embodiment of the present disclosure.

FIG. 3 is a timing diagram showing an example of operations of the sender and the receiver of FIG. 2 over time.

FIG. 4 is a block diagram showing an example of a sender and a receiver of FIG. 1, according to an embodiment of the present disclosure.

FIG. 5 is a timing diagram showing an example of operations of the sender and receiver of FIG. 4, according to an embodiment of the present disclosure.

FIG. 6 is a block diagram showing an example of the sender and the receiver of FIG. 1, according to an embodiment of the present disclosure.

FIG. 7A is a timing diagram showing an example of an operation of the sender of FIG. 6, according to an embodiment of the present disclosure, and FIG. 7B is a timing diagram showing an example of an operation of the receiver of FIG. 6, according to an embodiment of the present disclosure.

FIG. 8 is a flowchart showing an example of an operating method of the receiver of FIG. 6, according to an embodiment of the present disclosure.

FIG. 9 is a block diagram showing in detail an example of the receiver count block of FIG. 6, according to an embodiment of the present disclosure.

FIG. 10 is a block diagram showing in detail an example of the data sending block of FIG. 6, according to an embodiment of the present disclosure.

FIG. 11 is a block diagram showing in detail an example of the data receiving block of FIG. 6, according to an embodiment of the present disclosure.

FIG. 12 is a block diagram showing an electronic device, according to an embodiment of the present disclosure.

FIG. 13 is a drawing showing an automotive system, according to an embodiment of the present disclosure.

### DETAILED DESCRIPTION OF THE EMBODIMENTS

The following describes embodiments of the present disclosure in detail, providing sufficient clarity for a person skilled in the art to readily implement them.

The present disclosure relates to a sender and receiver system designed to improve error detection in electronic communications, particularly in scenarios where clock signal loss may occur. In typical electronic devices, communication between processing units relies on clock signals to synchronize data transmission. However, if the clock signal is lost or disrupted, data may be missed without immediate detection. This disclosure addresses the issue by implementing a system where the sender transmits a clock signal, an enable signal, and a heartbeat signal, while maintaining a sending count value. The receiver updates a corresponding receiving count value and compares it against the heartbeat signal to verify the integrity of data transmission. If a mismatch occurs, the receiver generates an error signal, ensuring that communication errors are promptly identified.

A key innovation of this system is the heartbeat signal, which serves as an additional mechanism to verify clock synchronization and data integrity. Unlike traditional error detection methods, which rely solely on parity checks or error correction codes, this system actively monitors whether data transmission remains in sync by checking if the receiving count aligns with the expected value when the heartbeat signal is received. This approach enables the system to detect clock signal loss, transmission errors, or unexpected communication failures in real-time, allowing the receiver to request data retransmission if needed. The technology is particularly useful in system-on-chip (SoC) architectures, computing systems, automotive applications, and cloud-based systems, where maintaining reliable high-speed data transmission is critical.

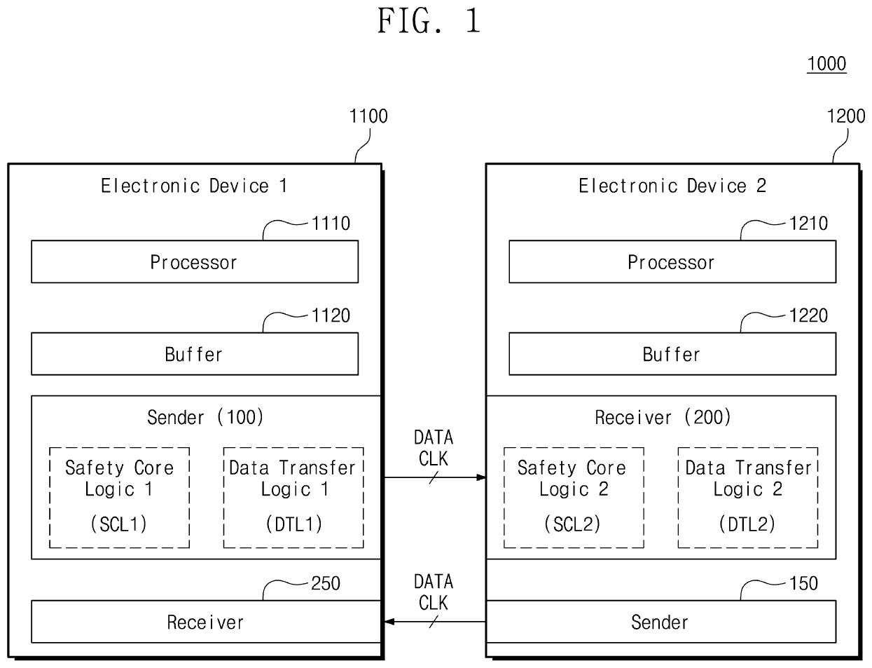

FIG. 1 is a block diagram showing an electronic system, according to an embodiment of the present disclosure. Referring to FIG. 1, an electronic system 1000 may include a first electronic device 1100 and a second electronic device 1200. The electronic devices 1100 and 1200 may include processors 1110 and 1210, buffers 1120 and 1220, senders 100 and 150, and receivers 250 and 200, respectively. The electronic system 1000 may be a multifunctional system capable of performing various functions. For example, the electronic system 1000 may be a mobile system, a computing system, a machine learning system, a cloud system, or an automotive system.

The electronic devices 1100 and 1200 may perform several functions. For example, each of the electronic devices 1100 and 1200 may implement various operations or roles of the electronic system 1000. In an embodiment, the electronic devices 1100 and 1200 may represent various devices or be incorporated into different devices, respectively. For example, each of the electronic devices 1100 and 1200 may be a system-on-chip (SoC), a processing unit, a personal computer (PC), a tablet PC, a laptop PC, a personal digital assistant (PDA), a smartphone, a server, or a datacenter, or be included therein.

The processors 1110 and 1210 may control the overall operations of the electronic devices 1100 and 1200, respectively. In an embodiment, the processors 1110 and 1210 may execute necessary operations for the functioning of the electronic devices 1100 and 1200, including running programs, program codes, or source codes. In an embodiment, the processors 1110 and 1210 may be a general-purpose processor or a special-purpose processor, or may include the general-purpose processor or the special-purpose processor. For example, the processors 1110 and 1210 may be general-purpose processors such as a central processing unit (CPU) or an application processor (AP), or special-purpose processors or accelerators such as a graphics processing unit (GPU), a neural processing unit (NPU), a tensor processing unit (TPU), or a neuromorphic processor (NP). Each of the electronic devices 1100 and 1200 is described as respectively including the processors 1110 and 1210. However, it should be understood that an embodiment including one or more additional processors 1110 and 1210 also falls within the scope of the present disclosure.

The buffers 1120 and 1220 may store data of the electronic devices 1100 and 1200. For example, the buffers 1120 and 1220 may temporarily store data of the electronic devices 1100 and 1200. In an embodiment, the buffers 1120 and 1220 may provide data to the processors 1110 and 1210 in response to requests of the processors 1110 and 1210. In an embodiment, the buffers 1120 and 1220 may store programs, program codes, source codes, an operating system (OS), or other instructions that define the operations of the electronic devices 1100 and 1200. For example, the buffers 1120 and 1220 may store source codes to be executed by the processors 1110 and 1210, and provide them to the processors 1110 and 1210 upon request.

In an embodiment, the buffers 1120 and 1220 may include memory devices. For example, the buffers 1120 and 1220 may be volatile memory devices or may include volatile memory devices. As a more detailed example, the buffers 1120 and 1220 may include dynamic random access memory (DRAM) or static RAM (SRAM). In an embodiment, the buffers 1120 and 1220 may further include a nonvolatile memory device (e.g., a NAND flash memory device).

Each of the senders 100 and 150 may transmit a signal to the outside. In an embodiment, the signals transmitted by the senders 100 and 150 may include data, source codes, or the like. For example, the senders 100 and 150 may transmit a clock signal CLK or data DATA from the electronic devices 1100 and 1200 to external components. In an embodiment, the senders 100 and 150 may transmit signals from the electronic devices 1100 and 1200 to other electronic devices, respectively. For example, the sender 100 of the first electronic device 1100 may transmit the data DATA or the clock signal CLK to the second electronic device 1200. The sender 150 of the second electronic device 1200 may transmit the data DATA or the clock signal CLK to the first electronic device 1100.

The receivers 200 and 250 may receive signals transmitted from external components. In an embodiment, the receivers 200 and 250 may receive the data DATA or the clock signal CLK, which is respectively transmitted from the electronic devices 1100 and 1200. For example, the receiver 250 of the first electronic device 1100 may receive the data DATA or the clock signal CLK from the second electronic device 1200. The receiver 200 of the second electronic device 1200 may receive the data DATA or the clock signal CLK from the first electronic device 1100.

While the transmission and reception of the data DATA or the clock signal CLK are illustrated between the senders 100 and 150 and the receivers 200 and 250, the scope of the present disclosure is not limited thereto. For example, as described below with reference to the accompanying drawings, the senders 100 and 150 and the receivers 200 and 250 may also exchange additional signals beyond the data DATA and the clock signal CLK.

In an embodiment, the sender 100 of the first electronic device 1100 may include first safety core logic SCL1, and first data transfer logic DTL1. The first safety core logic SCL1 may generate a signal to detect communication errors. The first data transfer logic DTL1 may perform the data DATA transmission operation of the sender 100. In an embodiment, the first safety core logic SCL1 may transmit an error detection signal to the receiver 200 of the second electronic device 1200. For example, the first safety core logic SCL1 may generate a signal to detect errors in the clock signal CLK and may transmit the generated signal to the receiver 200 of the second electronic device 1200. Additionally, the sender 150 of the second electronic device 1200 may include safety core logic identical or similar to the first safety core logic SCL1, and data transfer logic identical or similar to the first data transfer logic DTL1.

In an embodiment, the receiver 200 of the second electronic device 1200 may include second safety core logic SCL2 and second data transfer logic DTL2. The second safety core logic SCL2 may receive an error detection signal and determine whether a communication error has occurred. The second data transfer logic DTL2 may handle the reception of data DATA. In an embodiment, the second safety core logic SCL2 may receive an error detection from the sender 100 of the first electronic device 1100. For example, the second safety core logic SCL2 may receive a signal indicating an error in the clock signal CLK and use this signal to detect whether an error occurs in the clock signal CLK. In an embodiment, the receiver 250 of the first electronic device 1100 may include safety core logic identical or similar to the first safety core logic SCL1, and data transfer logic identical or similar to the first data transfer logic DTL1.

The electronic devices 1100 and 1200 illustrated and described in FIG. 1 are merely examples, and the scope of the present disclosure is not limited thereto. It should be understood that embodiments in which the electronic devices 1100 and 1200 include additional components (e.g., a user interface, etc.) not illustrated or described in FIG. 1 also fall within the scope of the present disclosure. Likewise, embodiments in which the electronic devices 1100 and 1200 omit certain configurations illustrated in FIG. 1 are also within the scope of the present disclosure.

In an embodiment, the electronic devices 1100 and 1200 may not include the processors 1110 and 1210 or the buffers 1120 and 1220 and may be system-on-chips (SoCs) that perform one or more functions. For example, the first electronic device 1100 may be a first SoC that performs one or more first functions, including the sender 100, and the second electronic device 1200 may be a second SoC that performs one or more second functions, including the receiver 200.

During communication between the senders 100 and 150 and the receivers 200 and 250, portions of a signal may be altered, distorted, lost, or missed due to environmental factors. For example, signal-noise ratio (SNR) degradation may occur due to factors such as inter-symbol interference (ISI) or noise interference, leading to signal deformation, distortion, or loss. Referring to the drawings below, when a portion of a signal (e.g., the clock signal CLK) is transformed, distorted or lost during communication between the senders 100 and 150 and the receivers 200 and 250, the receivers 200 and 250 using the safety core logic SCL1 or SCL2 can detect communication errors. The following describes the operation of the receivers 200 and 250, and the electronic devices 1100 and 1200 that incorporate them.

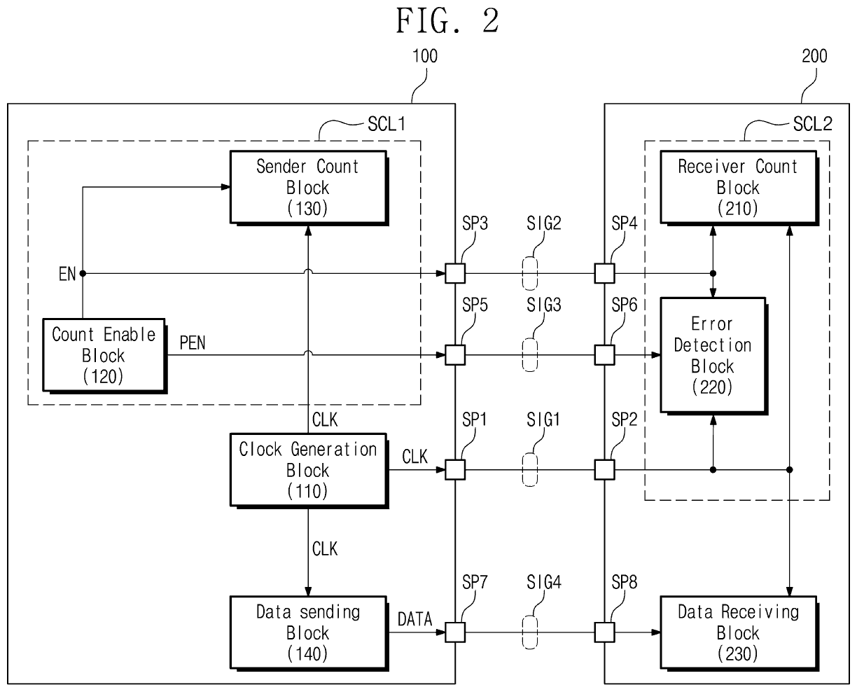

FIG. 2 is a block diagram showing in detail an example of the sender and the receiver of FIG. 1, according to an embodiment of the present disclosure. The sender 100 may correspond to the senders 100 and 150 of FIG. 1, and the receiver 200 may correspond to the receivers 200 and 250 of FIG. 1. Referring to FIG. 2, the sender 100 may include a clock generation block 110, a count enable block 120, a sender count block 130, and a data sending block 140. The receiver 200 may include a receiver count block 210, an error detection block 220, and a data receiving block 230. Each block of the sender 100 and the receiver 200 may be individually implemented as a circuit.

In an embodiment, the count enable block 120 and the sender count block 130 may constitute the first safety core logic SCL1 of FIG. 1 or may be included in the first safety core logic SCL1 of FIG. 1. In an embodiment, the receiver count block 210 and the error detection block 220 may constitute the second safety core logic SCL2 of FIG. 1 or may be included in the second safety core logic SCL2 of FIG. 2. In an embodiment, the data sending block 140 may constitute the first data transfer logic DTL1 of FIG. 1 or may be included in the first data transfer logic DTL1 of FIG. 1. The data receiving block 230 may constitute the second data transfer logic DTL2 of FIG. 1 or may be included in the second data transfer logic DTL2 of FIG. 1. In an embodiment, the sender 100 and the receiver 200 may be connected via first to fourth signal lines SIG1, SIG2, SIG3, and SIG4. The number of signal lines is just an example and the scope of the present disclosure is not limited thereto.

The clock generation block 110 may generate the clock signal CLK. The clock signal CLK may be a signal used for the operations of the sender 100 and the receiver 200. In other words, the clock signal CLK may be used to synchronize the operations of the sender 100 and the receiver 200. In an embodiment, the clock generation block 110 may transmit the generated clock signal CLK to other blocks. For example, the clock generation block 110 may transmit the generated clock signal CLK to the sender count block 130 and the data sending block 140. The clock generation block 110 may also transmit the generated clock signal CLK to the receiver count block 210, the data receiving block 230, and the error detection block 220 of the receiver 200 through a first signal pin SP1, the first signal line SIG1, and a second signal pin SP2.

In FIG. 2, an embodiment in which the clock generation block 110 is included in the sender 100 is described, but this is just an example and the scope of the present disclosure is not limited thereto. For example, the sender 100 may receive the clock signal CLK from a clock generation block external to the sender 100, use it for its operation, and transmit it to the blocks 210, 220, and 230 of the receiver 200 through the second signal line SIG2. The external clock generation block may be located either within or outside the electronic device (e.g., the first electronic device 1100) that includes the sender 100.

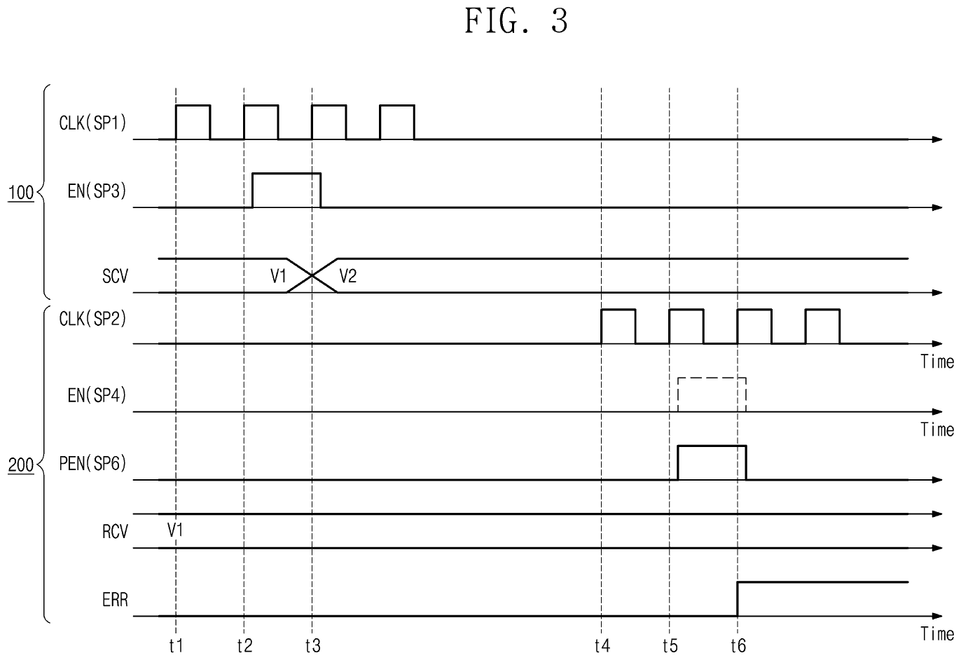

In an embodiment, the period of the clock signal CLK generated by the clock generation block 110 may be determined based on factors such as the data transmission/reception speed, the operating speed of an electronic device (e.g., the first electronic device 1100 of FIG. 1) that includes the sender 100, or other relevant parameters. An example of a clock signal generated by the clock generation block 110 is described with reference to FIG. 3.

The count enable block 120 may generate an enable signal EN to be transmitted to the sender count block 130. In an embodiment, the count enable block 120 may generate the enable signal EN in response to the start of data transfer. For example, the count enable block 120 may receive a notification of the data transfer initiation from an external source (e.g., the processor 1110 of FIG. 1) and generate the enable signal EN in response to the notification. For example, the count enable block 120 may generate the enable signal EN at a first level (e.g., logic HIGH) and maintain it for the duration of the clock signal CLK period, in response to the start of data transfer. In other words, the enable signal EN from the count enable block 120 serves as the indicator of the data transfer initiation.

In an embodiment, the count enable block 120 may transition the state of the enable signal EN. For example, the count enable block 120 may transition the state of the enable signal EN in response to the start of data transfer. In an embodiment, the enable signal EN may normally remain at logic LOW and transition to logic HIGH in response to the start of data transfer. In other words, the state transition of the enable signal EN may indicate that data transfer has begun.

In an embodiment, if data transfer of the count enable block 120 is continuous, the enable signal EN may also be generated continuously. For example, during continuous data transfer, the count enable block 120 may either continuously generate the enable signal EN at a first level (e.g., until a specified time after the last data transfer begins) or maintain the enable signal EN at the first level. Additionally, when the data transfer of the count enable block 120 is continuous, the state transition of the enable signal EN may be maintained. For example, if data transfer remains continuous, the count enable block 120 may maintain the enable signal EN at logic HIGH.

While the enable signal EN is described as normally maintaining a logic LOW state, this is merely an example and does not limited the scope of the present disclosure. For example, an embodiment in which the enable signal EN is normally maintained at logic HIGH also falls within the scope of the present disclosure. In an embodiment, the time (or length) for which the enable signal EN remains at logic HIGH (or logic LOW) may be equal to or similar to the period of the clock signal CLK. The enable signal EN is described in more detail with reference to FIG. 3.

The count enable block 120 may generate a parity enable signal PEN in addition to the enable signal EN. In an embodiment, the parity enable signal PEN may have the same waveform and period as the enable signal EN. In an embodiment, the parity enable signal PEN may be a signal whose amplitude is inverted with respect to the enable signal EN. The parity enable signal PEN will be described in detail with reference to FIG. 3.

The count enable block 120 may transmit the generated enable signal EN to other blocks. For example, the count enable block 120 may transmit the enable signal EN to the sender count block 130. As another example, the count enable block 120 may deliver the enable signal EN to the receiver count block 210 and the error detection block 220 of the receiver 200 through a third signal pin SP3, the second signal line SIG2, and a fourth signal pin SP4. The count enable block 120 may transmit the generated parity enable signal PEN to the receiver 200. For example, the count enable block 120 may transmit the parity enable signal PEN to the error detection block 220 through a fifth signal pin SP5, the third signal line SIG3, and a sixth signal pin SP6.

The sender count block 130 may change, update, or manage a sending count value of the sender 100. In an embodiment, the sender count block 130 may change the sending count value in response to the enable signal EN and the clock signal CLK. For example, the sender count block 130 may increase the sending count value by 1 in response to the enable signal EN being at logic HIGH and the rising edge of the clock signal CLK. Conversely, as another example, the sender count block 130 may decrease the sending count value by 1 in response to the enable signal EN being at logic HIGH and the rising edge of the clock signal CLK.

In an embodiment, the sender count block 130 may manage a data transfer time point, a data transfer count, and a range of data transmitted at one time based on the sending count value. In other words, the sender count block 130 may manage the data transfer timing, the number of data transfers, and the range of data transmitted at a given time based on the sending count value. For example, while the sending count value of the sender count block 130 is maintained, a single piece of data may be transmitted to the receiver 200.

In an embodiment, the sender count block 130 may update and manage the sending count value using a circular counter. For example, when the sending count value reaches its maximum, the sender count block 130 may reset it to the minimum value. Specifically, if the sending count value is represented in 4 bits and its value before the update is “1111”, the next sending count value may be “0000”.

In an embodiment, an electronic device (e.g., the first electronic device 1100 of FIG. 1) may manage the data transfer time point, the data transfer count, and the range of data transmitted at a given time based on the sending count value of the sender count block 130 within the sender 100. More detailed operations of the sender count block 130 and the sending count value are described further with reference to FIG. 3.

The data sending block 140 may transmit the data DATA in response to the clock signal CLK. In an embodiment, the data DATA transmitted by the data sending block 140 may be data received from the outside of the sender 100. For example, the data DATA transmitted by the data sending block 140 may be data received from the processor 1110 of FIG. 1 or the buffer 1120 of FIG. 1.

In an embodiment, the data sending block 140 may transmit the data DATA through one or more signal lines. For example, the data sending block 140 may transmit the data DATA to the data receiving block 230 of the receiver 200 through the fourth signal line SIG4, which may include multiple signal lines. Alternatively, the data sending block 140 may transmit the data DATA to the data receiving block 230 through the fourth signal line SIG4, which may include one signal line. In this case, the data DATA of the data sending block 140 may be converted from parallel to serial format using serializer-deserializer (SERDES). In an embodiment, the data sending block 140 may transmit the data DATA to the data receiving block 230 through a seventh signal pin SP7, the fourth signal line SIG4, and an eighth signal pin SP8.

The receiver count block 210 may change, update, or manage a receiving count value of the receiver 200. In an embodiment, the receiver count block 210 may be identical or similar to the sender count block 130 and may function in a manner similar to its operation. For example, the receiver count block 210 may change or update the receiving count value in response to the enable signal EN and the clock signal CLK.

In an embodiment, the receiver count block 210 may update and manage the receiving count value using a circular counter. For example, when the receiving count value reaches its maximum, the receiver count block 210 may reset it to the minimum value. Specifically, if the receiving count value is represented in 4 bits and the receiving count value before the update is “1111”, the next receiving count value may be “0000”.

In an embodiment, an electronic device (e.g., the second electronic device 1200 of FIG. 1) may manage a data reception time point, a data reception count, and a range of data received at a given time based on the receiving count value of the receiver count block 210 within the receiver 200. More detailed operations of the receiver count block 210 and the receiving count value are described further with reference to FIG. 3.

The error detection block 220 may determine whether a communication error has occurred between the sender 100 and the receiver 200. In an embodiment, the error detection block 220 may detect error based on the enable signal EN and the parity enable signal PEN. Additionally, the error detection block 220 may operate in response to the clock signal CLK. If an error is detected, the error detection block 220 may notify an electronic device that includes the receiver 200 (e.g., the second electronic device 1200 of FIG. 2). More detailed operations of the error detection block 220 will be described with reference to FIG. 3.

The data receiving block 230 may receive the data DATA transmitted by the data sending block 140. In an embodiment, the data receiving block 230 may process, sense, capture, or extract the data DATA received in response to the clock signal CLK. For example, the data receiving block 230 may capture or extract the data DATA from a signal, which is received through the eighth signal pin SP8, based on the clock signal CLK. The data receiving block 230 may deliver the received data to other components (e.g., the processor 1210 or the buffer 1220) of the second electronic device 1200 of FIG. 1 that includes the receiver 200.

FIG. 2 describes an embodiment in which the sender count block 130 updates the sending count value by incrementing it. However, the scope of the present disclosure is not limited thereto. An embodiment in which the sender count block 130 updates the sending count value by decrementing it, is within the scope of the present disclosure. Similarly, FIG. 2 describes an embodiment where the receiver count block 210 updates the receiving count value by incrementing it. However, an embodiment where the receiver count block 210 updates the receiving count value by decrementing the receiving count value is also within the scope of the present disclosure. Additionally, while FIG. 2 illustrates an example in which the sender count block 130 updates the sending count value by 1, an embodiment in which it updates the sending count value by an arbitrary value is also within the scope of the present disclosure. Likewise, while the receiver count block 210 is described as updating the receiving count value by 1, an embodiment, in which it updates the receiving count value by an arbitrary value is also considered within the scope of the present disclosure.

FIG. 3 is a timing diagram showing an example of operations of the sender and receiver of FIG. 2, according to an embodiment of the present disclosure. Referring to FIG. 3, the clock signal CLK of the sender 100, the enable signal EN of the sender 100, a sending count value SCV, the clock signal CLK of the receiver 200, the enable signal EN of the receiver 200, the parity enable signal PEN of the receiver 200, and a receiving count value RCV, and an error signal ERR are illustrated over time. An example of the operations of the sender 100 and the receiver 200 according to an embodiment of the present disclosure is described with reference to FIGS. 2 and 3. Moreover, error detection in communication between the sender 100 and the receiver 200 according to an embodiment of the present disclosure is also described with reference to FIGS. 2 and 3.

Referring to FIGS. 2 and 3 together, the level of the clock signal CLK of the sender 100 may be the signal level of the first signal pin SP1. For example, the clock signal CLK of the sender 100 may have a first rising edge at a first time point t1 and may further have three rising edges in succession. A level of the enable signal EN of the sender 100 may be a signal level of the third signal pin SP3. In FIG. 3, the level of the enable signal EN of the sender 100 transitions to logic HIGH after a second time point t2, maintains logic HIGH for the duration of the clock signal CLK period, and then returns to logic LOW.

The sending count value SCV may be managed by the sender count block 130. The sending count value SCV may have a first value V1 at the first time point t1. The sending count value SCV may be increased by 1 in response to the rising edge of the clock signal CLK at a third time point t3, provided that the level of the enable signal EN at the third time point t3 is at logic HIGH. The sending count value SCV may have a second value V2 after the third time point t3. In an embodiment, the second value V2 may be greater than the first value V1 by ‘1’.

The level of the clock signal CLK received by the receiver 200 may be a signal level of the second signal pin SP2. The clock signal CLK of the receiver 200 may have four rising edges from a fourth time point t4. In an embodiment, the time difference between the first time point t1 and the fourth time point t4 represents the communication time or delay between the sender 100 and the receiver 200. The time difference between the first time point t1 and the fourth time point t4 in FIG. 2 is merely an example and the scope of the present disclosure is not limited thereto. For example, an embodiment in which the time difference between two time points has an arbitrary value is also within the scope of the present disclosure.

The level of the enable signal EN received by the receiver 200 may be the signal level of the fourth signal pin SP4. For example, during the communication process, the enable signal EN may be lost or omitted, causing the enable signal EN of the receiver 200 to remain at logic LOW without changing. In FIG. 3, a dotted line represents the expected the signal level when the enable signal EN of the receiver 200 is not lost during the communication process.

The level of the parity enable signal PEN received by the receiver 200 may be a signal level of the sixth signal pin SP6. For example, the parity enable signal PEN may have the same form as the enable signal EN, but with a waveform that is delayed by the communication time difference relative to the signal level of the third signal pin SP3.

The receiving count value RCV may initially have the first value V1. At a sixth time point t6, the receiving count value RCV may remain unchanged due to the partial loss of the enable signal EN. In other words, the receiving count value RCV may maintain its initial value without being updated, resulting in a discrepancy between the receiving count value RCV and the sending count value SCV even after the sixth time point t6.

The error signal ERR may be a signal generated by the error detection block 220, and may indicate that an error occurs when the error signal ERR has logic HIGH. In an embodiment, the error detection block 220 may detect that an error occurs, based on a difference between the enable signal EN and the parity enable signal PEN. In an embodiment, the error detection block 220 may detect that an error occurs, and may transition the error signal ERR in response to the clock signal CLK being at a rising edge. For example, the error detection block 220 may transition the error signal ERR to logic HIGH when the clock signal CLK is at a rising edge at the sixth time point t6 and the enable signal EN differs from the parity enable signal PEN.

The second electronic device 1200 of FIG. 1, which includes the receiver 200, may detect a communication error when the error signal ERR transitions to logic HIGH or remains at logic HIGH. In an embodiment, upon detecting a communication error, the second electronic device 1200 may request data retransmission through the sender 150.

The sender 100 and the receiver 200 described with reference to FIGS. 2 and 3 may detect an error of the enable signal EN. When an error occurs in the data DATA, the sender 100 and the receiver 200 may detect and correct the error using an error correction code (ECC) technique such as parity encoding of the data DATA.

When the clock signal CLK transmitted through the first signal line SIG1 is distorted or lost, the receiver 200 of FIGS. 2 and 3 may have difficulty detecting the error. Since such distortion or loss in the communication process between the sender 100 and the receiver 200 prevents the data receiving block 230 from correctly detecting data, it is essential to detect any transformation or loss of the clock signal CLK. The structure and operation of a sender and receiver capable of detecting clock signal CLK distortion or loss are described with reference to the drawings below.

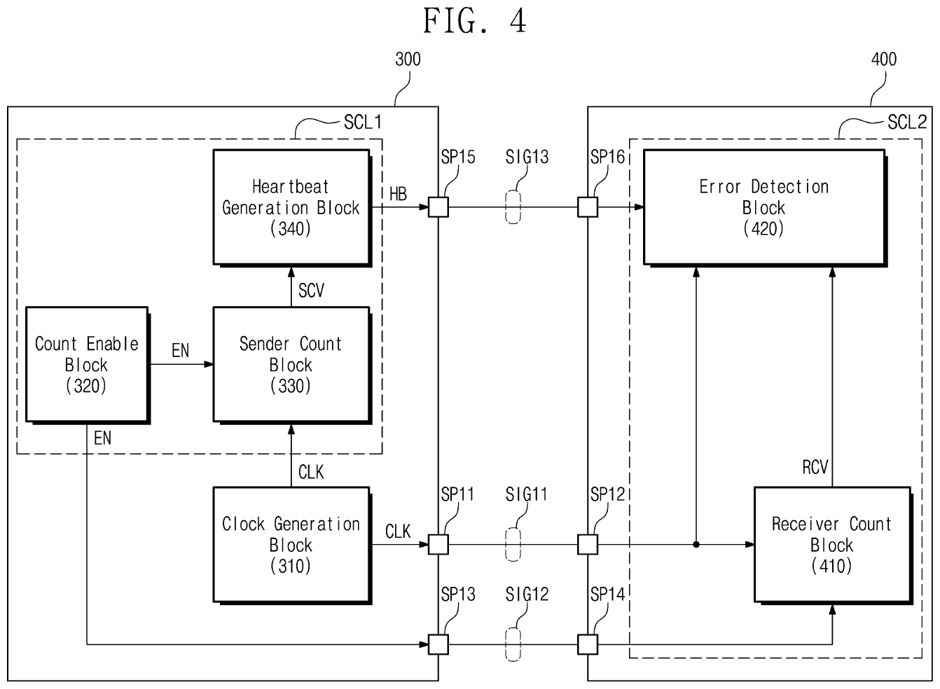

FIG. 4 is a block diagram showing an example of a sender and a receiver of FIG. 1, according to an embodiment of the present disclosure. A sender 300 may correspond to the senders 100 and 150 of FIG. 1. Likewise, the receiver 400 may correspond to the receivers 200 and 250 of FIG. 1. Referring to FIG. 4, the sender 300 may include a clock generation block 310, a count enable block 320, a sender count block 330, and a heartbeat generation block 340. The receiver 400 may include a receiver count block 410 and an error detection block 420. Each block of the sender 300 and the receiver 400 may be individually implemented as a circuit.

In an embodiment, the count enable block 320, the sender count block 330, and the heartbeat generation block 340 may constitute the first safety core logic SCL1 of FIG. 1 or may be included in the first safety core logic SCL1 of FIG. 1. In an embodiment, the receiver count block 410 and the error detection block 420 may constitute the second safety core logic SCL2 of FIG. 1 or may be included in the second safety core logic SCL2 of FIG. 1. In FIG. 4, the sender 300 and the receiver 400 may be connected through three signal lines SIG11, SIG12, and SIG13.

The clock generation block 310 may generate the clock signal CLK. The clock signal CLK may be a signal used for the operations of the sender 300 and the receiver 400. The clock generation block 310 may be identical or similar to the clock generation block 110 of FIG. 2. The clock generation block 310 may operate identically or similarly to the clock generation block 110 of FIG. 2. For example, the clock generation block 310 may provide the clock signal CLK to the sender count block 330 of the sender 300, and may deliver the clock signal CLK to the receiver count block 410 or the error detection block 420 of the receiver 400 through an eleventh signal pin SP11, the eleventh signal line SIG11, and a twelfth signal pin SP12.

The count enable block 320 may generate an enable signal EN to be transmitted to the sender count block 330. In an embodiment, in response to the start of data transfer, the count enable block 320 may generate the enable signal EN or may transition the state of the enable signal EN. In other words, the enable signal EN or the state transition of the enable signal EN may indicate the start of data transfer.

The count enable block 320 may be identical or similar to the count enable block 120 of FIG. 2. The count enable block 320 may operate identically or similarly to the count enable block 120 of FIG. 2. The enable signal EN generated by the count enable block 320 may be identical or similar to the enable signal EN of the count enable block 120 of FIG. 2.

The count enable block 320 may deliver the generated enable signal EN to other blocks. For example, the count enable block 320 may deliver the generated enable signal EN to the receiver count block 410 through a thirteenth signal pin SP13, the twelfth signal line SIG12, and a fourteenth signal pin SP14. In an embodiment, the count enable block 320 may further generate a parity enable signal (e.g., identical or similar to the parity enable signal PEN of FIG. 2) and may transmit the generated parity enable signal to the receiver 400 through a separate signal line.

The sender count block 330 may change, update, or manage a sending count value of the sender 300. In an embodiment, the sender count block 330 may change or update the sending count value in response to the enable signal EN and the clock signal CLK. The sender count block 330 may be identical or similar to the sender count block 130 of FIG. 2, and may operate identically or similarly to the sender count block 130 of FIG. 2.

In an embodiment, the sender count block 330 may change, update, or manage the sending count value by using a circular counter. For example, when changing the sending count value reaches its maximum, the sender count block 330 may reset it to the minimum value. As a more detailed example, when the sending count value is represented in 2 bits and the sending count value before the update is “11”, the next sending count value may be “00”. In an embodiment, the sender count block 330 may deliver the sending count value SCV to other blocks. For example, the sender count block 330 may deliver the sending count value SCV to the heartbeat generation block 340.

The heartbeat generation block 340 may generate a heartbeat signal HB. In an embodiment, the heartbeat generation block 340 may generate the heartbeat signal HB based on the sending count value SCV received from the sender count block 330. For example, the heartbeat generation block 340 may generate the heartbeat signal HB when the sending count value SCV reaches either its maximum or minimum value. In this case, the heartbeat signal HB may have a second level (e.g., logic HIGH) for the duration of one clock signal CLK period.

In an embodiment, the heartbeat generation block 340 may transition the state of the heartbeat signal HB based on the sending count value SCV. For example, it may normally maintain the heartbeat signal HB at logic LOW and transition it to logic HIGH when the sending count value SCV meets a certain condition. (It should be understood that the opposite case, where the heartbeat signal HB is normally HIGH and transitions to LOW, is also within the scope of the present disclosure.) In an embodiment, the heartbeat generation block 340 may transition the heartbeat signal HB to logic HIGH, maintain it at logic HIGH for a specific duration, and then transition it back to logic LOW. For example, the heartbeat generation block 340 may transition the heartbeat signal HB to logic HIGH, maintain it at logic HIGH for the duration of one clock signal CLK period, and then transition it back to logic LOW.

FIG. 4 illustrates an embodiment where the heartbeat generation block 340 receives the sending count value SCV and generates the heartbeat signal HB upon detecting that the SCV has reached its maximum value. However, the scope of the present disclosure is not limited to this configuration. In an embodiment, the heartbeat generation block 340 may also receive the enable signal EN and the clock signal CLK and accumulate occurrences of the enable signal EN. When the accumulated level of the enable signal EN reaches a predefined threshold value, the heartbeat signal HB may be generated.

The heartbeat generation block 340 may deliver the generated heartbeat signal HB to the receiver 400. For example, the heartbeat generation block 340 may transmit the generated heartbeat signal HB to the error detection block 420 of the receiver 400 through a fifteenth signal pin SP15, the thirteenth signal line SIG13, and a sixteenth signal pin SP16.

The receiver count block 410 may change, update, or manage a receiving count value of the receiver 400. In an embodiment, the receiver count block 410 may change or update a receiving count value in response to the enable signal EN and the clock signal CLK. The receiver count block 410 may be identical or similar to the receiver count block 210 of FIG. 2, and may operate identically or similarly to the receiver count block 210 of FIG. 2.

In an embodiment, the receiver count block 410 may change, update, or manage the receiving count value by using a circular counter. For example, when the receiving count value reaches its maximum, the receiver count block 410 may reset it to the minimum value. As a more detailed example, when the receiving count value is represented in 2 bits and the receiving count value before the update is “11”, the next receiving count value may be “00”.

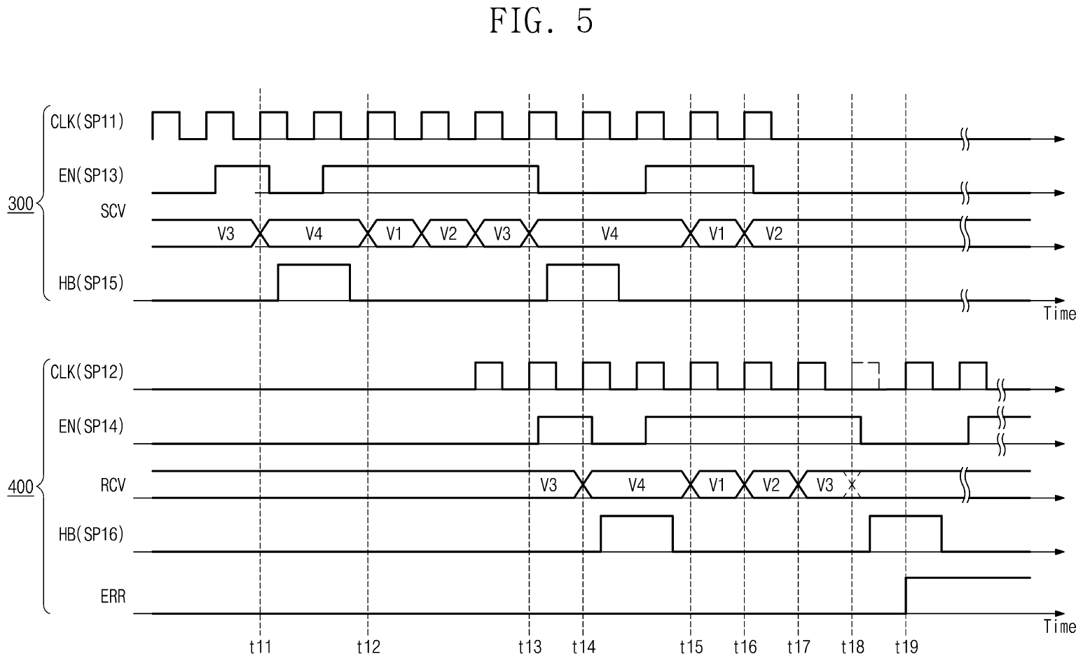

The error detection block 420 may determine whether a communication error has occurred between the sender 300 and the receiver 400. In an embodiment, the error detection block 420 may detect communication errors based on the heartbeat signal HB and the receiving count value RCV. For example, if the error detection block 420 receives the heartbeat signal HB while the receiving count value RCV is not at its maximum value (or alternatively, at its minimum value or any other predefined value), the error detection block 420 may identify a communication error. As another example, if the error detection block 420 does not receive the heartbeat signal HB when the receiving count value RCV is at its maximum value (or alternatively, at its minimum value or any other predefined value), the error detection block 420 may also detect a communication error. In an embodiment, the error detection block 420 may detect an error caused by loss of the clock signal CLK based on the heartbeat signal HB. The error detection of the clock signal CLK of the error detection block 420 will be described in more detail with reference to FIG. 5.

FIG. 4 does not illustrate a data sending block and a data receiving block, but the scope of the present disclosure is not limited thereto. It should also be understood that an embodiment, in which the sender 300 includes a data sending block identical or similar to the data sending block 140 of FIG. 2 or in which the receiver 400 further includes a data receiving block identical or similar to the data receiving block 230 of FIG. 2, is also within the scope of the present disclosure. For example, the sender 300 may include a data sending block operating in response to the clock signal CLK, and the receiver 400 may include a data receiving block operating in response to the clock signal CLK. The data sending block and the data receiving block may be connected through signal lines other than the eleventh to thirteenth signal lines SIG11 to SIG13.

In FIG. 4, an embodiment in which the sender count block 330 updates the sending count value based on the sender count block 130 increasing the sending count value is described, but the scope of the present disclosure is not limited thereto. It should also be understood that an embodiment, in which the sender count block 330 updates the sending count value based on the sender count block 130 decreasing the sending count value, is within the scope of the present disclosure. In FIG. 4, an embodiment in which the receiver count block 410 updates the receiving count value based on the receiver count block 210 increasing the receiving count value is described, but the scope of the present disclosure is not limited thereto. An embodiment in which the receiver count block 410 updates the receiving count value based on the receiver count block 410 decreasing the receiving count value should be understood to fall within the scope of the present disclosure. In FIG. 4, an embodiment in which the sender count block 330 updates the sending count value by 1 is described as an example, but it should be understood that an embodiment in which the sender count block 330 updates th e sending count value by another value is also within the scope of the present disclosure. Likewise, an embodiment in which the receiver count block 410 updates the receiving count value by 1 is described. However, it should be understood that an embodiment, in which the receiver count block 410 updates the receiving count value by another value, is also within the scope of the present disclosure.

FIG. 5 is a timing diagram showing an example of operations of the sender and receiver of FIG. 4, according to an embodiment of the present disclosure. Referring to FIG. 5, changes of the clock signal CLK of the sender 300, the enable signal EN of the sender 300, the sending count value SCV, the heartbeat signal HB of the sender 300, the clock signal CLK of the receiver 400, the enable signal EN of the receiver 400, the receiving count value RCV, the heartbeat signal HB of the receiver 400, and the error signal ERR are illustrated over time. In FIG. 5, a horizontal axis of each timing diagram may indicate time.

Referring to FIGS. 4 and 5 together, the level of the clock signal CLK of the sender 300 may be the signal level of the eleventh signal pin SP11. For example, the clock signal CLK of the sender 300 may generate a rising edge with a specific period. The level of the enable signal EN of the sender 300 may be the signal level of the thirteenth signal pin SP13. For example, the level of the enable signal EN of the sender 300 may transition to logic HIGH based on the data transfer start time. In FIG. 5, since the data transfer continuously occurs between a twelfth time point t12 and a thirteenth time point t13, the enable signal EN may remain at logic HIGH.

The sending count value SCV may be changed or updated depending on the enable signal EN and the clock signal CLK. For example, the sending count value SCV may initially be a third value V3. The sending count value SCV may be changed to a fourth value V4 in response to the rising edge of the clock signal CLK at an eleventh time point t11, provided the enable signal EN is at logic HIGH. (Here, the fourth value V4 may represent the maximum value of the sending count value SCV in a circular counting sequence.)

After the twelfth time point t12 of the sending count value SCV, in response to the enable signal EN being maintained at logic HIGH and the rising edge of the clock signal CLK, the sending count value SCV may sequentially have the first value V1, the second value V2, and the third value V3, and may be changed to the fourth value V4 at the thirteenth time point t13. At a fifteenth time point t15 and a sixteenth time point t16, the sending count value SCV may be respectively changed to the first value V1 and the second value V2 in response to the enable signal EN being at logic HIGH and the rising edge of the clock signal CLK.

The level of the heartbeat signal HB of the sender 300 may be a signal level of the fifteenth signal pin SP15. The level of the heartbeat signal HB of the sender 300 may transition to logic HIGH after (or immediately after) the eleventh time point t11 in response to the sending count value SCV at the eleventh time point t11 reaching the fourth value V4. The heartbeat signal HB may then remain at logic HIGH for the duration of the clock signal CLK period. Likewise, the level of the heartbeat signal HB may transition to logic HIGH after (or immediately after) the thirteenth time point t13 when the sending count value SCV at the thirteenth time point t13 equals the fourth value V4, maintaining logic HIGH for the duration of the clock signal CLK period. In FIG. 5, the duration for which the heartbeat signal HB remains at logic HIGH is provided as an example, and the scope of the present disclosure is not limited to this specific timing. For example, the time during which the heartbeat signal HB stays at logic HIGH may be shorter or longer than the period of the clock signal CLK.

In FIG. 5, it is described that the sending count value SCV increases, but the scope of the present disclosure is not limited thereto. It should be understood that an embodiment in which the sending count value SCV sequentially decreases is also within the scope of the present disclosure. In this case, the signal level of the heartbeat signal HB may transition to logic HIGH in response to the sending count value SCV having its minimum value.

The clock signal CLK of the receiver 400 may be the clock signal CLK received by the receiver 400, and the level of the clock signal CLK of the receiver 400 may be the signal level of the twelfth signal pin SP12. For example, communication between the sender 300 and the receiver 400 may be delayed by a time difference between the eleventh time point t11 and the fourteenth time point t14. However, this is just an example and the scope of the present disclosure is not limited thereto. The level of the clock signal CLK of the receiver 400 may periodically have a rising edge. For example, referring to FIG. 5, the level of the clock signal CLK of the receiver 400 may not have a rising edge at an eighteenth time point t18 due to the loss of the clock signal CLK. (The dotted line may indicate a clock signal when no error occurs.)

The enable signal EN of the receiver 400 may be the enable signal EN received by the receiver 400, and the level of the enable signal EN of the receiver 400 may be the signal level of the fourteenth signal pin SP14. The waveform of the level of the enable signal EN of the receiver 400 may be the same as the waveform of the level of the enable signal EN of the sender 300. There may be a delay, corresponding to the time difference between the eleventh time point t11 and the fourteenth time point t14, in the waveform of the enable signal EN level of the sender 300.

The receiving count value RCV may be updated in response to the clock signal CLK of the receiver 400 and the enable signal EN of the receiver 400. For example, the receiving count value RCV may initially have the third value V3, and be updated to the fourth value V4 at the fourteenth time point t14. Like the sending count value SCV, the receiving count value RCV may be a value of a circular counter, and the receiving count value RCV may be sequentially updated to the first value V1, the second value V2, and the third value V3 at the fifteenth time point t15, the sixteenth time point t16, and the seventeenth time point t17, respectively.

Since there is a loss of the clock signal CLK at an eighteenth time point t18, the receiving count value RCV may not be updated. In other words, unlike the sending count value SCV of the thirteenth time point t13, the receiving count value RCV of an eighteenth time point t18 may maintain the third value V3. Afterwards, the receiving count value RCV may be updated to the fourth value V4 in response to the level of the enable signal EN being logic HIGH, and the rising edge of the clock signal CLK.

The heartbeat signal HB of the receiver 400 may be the heartbeat signal HB received by the receiver 400, and the level of the heartbeat signal HB of the receiver 400 may be the signal level of the sixteenth signal pin SP16. The level and waveform of the heartbeat signal HB of the receiver 400 may be the same as the level and waveform of the heartbeat signal HB of the sender 300. There may be a delay, corresponding to the time difference between the eleventh time point t11 and the fourteenth time point t14, in the heartbeat signal HB of the sender 300.

The error signal ERR may be a signal detected by the error detection block 420 based on the receiving count value RCV and the heartbeat signal HB. In an embodiment, a logic HIGH level of the error signal ERR may indicate the occurrence of a communication error. For example, after the eighteenth time point t18, the error detection block 420 may receive the heartbeat signal HB, and the receiving count value RCV received by the error detection block 420 may be the third value V3. In other words, since the receiving count value RCV is not the maximum value at the time point at which the heartbeat signal HB is received, the error detection block 420 may determine that an error occurs. In an embodiment, the error detection block 420 may change the level of the error signal ERR to logic HIGH in response to a rising edge of the clock signal CLK, to thus indicate that a communication error has occurred between the sender 300 and the receiver 400. For example, the error detection block 420 may change the level of the error signal ERR to logic HIGH at a nineteenth time point t19 in response to a rising edge of the clock signal CLK of the receiver 400.

The sender 300 and the receiver 400, which are capable of detecting an error of the clock signal CLK, and operations thereof are described with reference to FIGS. 4 and 5. In addition to detecting the loss of the enable signal EN described in FIGS. 2 and 3, the sender 300 and the receiver 400 of FIGS. 4 and 5 may detect the loss of the clock signal CLK using the heartbeat signal HB. FIG. 5 is an example for describing an operation in which the receiver 400 detects an error due to the loss of the clock signal CLK, but the scope of the present disclosure should not be construed as being limited thereto. It should be understood that an embodiment in which the clock signal CLK is lost at an arbitrary time point and the error detection block 420 detects an error based on the operations described in FIGS. 4 and 5 is also within the scope of the present disclosure. When the enable signal EN is lost, the receiving count value RCV is not updated, leading to error detection, similar to detecting an error cause by the loss of the clock signal CLK. Moreover, in the case of a data error, errors may be detected and corrected using an error correction code (ECC) encoding or ECC decoding method applied to the data.

In an embodiment, the receiver 400 may provide an electronic device (e.g., the second electronic device 1200 of FIG. 1) including the receiver 400 with a notification that a communication error occurs. In an embodiment, an electronic device (e.g., the second electronic device 1200 of FIG. 1) may request another electronic device (e.g., the first electronic device 1100) to re-transmit data corresponding to the heartbeat signal HB in which an error is detected, as well as any subsequent data, through a sender (e.g., the sender 150).

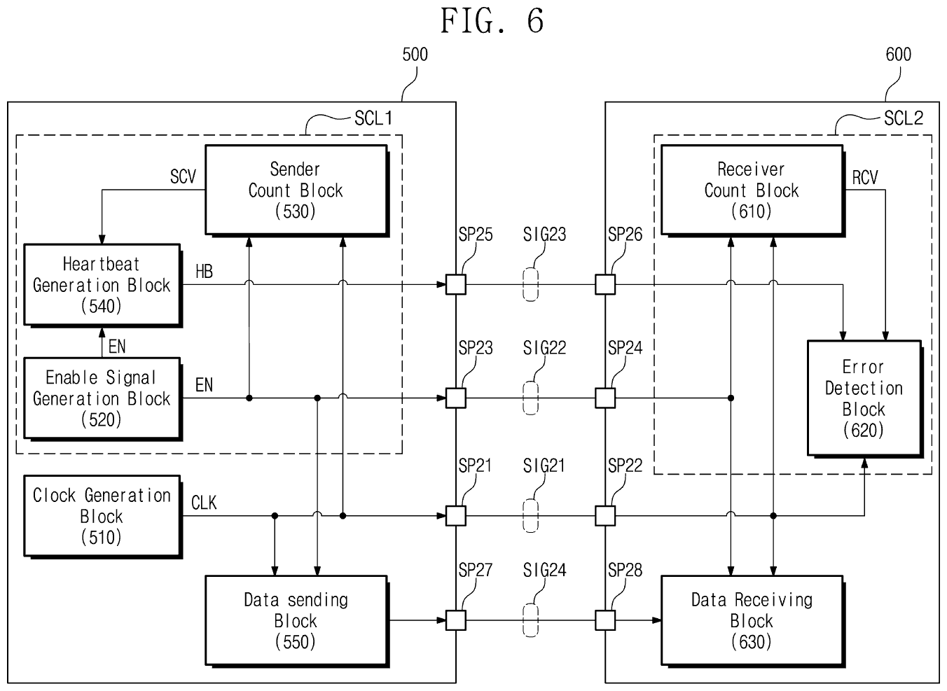

FIG. 6 is a block diagram showing in detail an example of the sender and the receiver of FIG. 1, according to an embodiment of the present disclosure. A sender 500 may correspond to the senders 100 and 150 of FIG. 1, and a receiver 600 may correspond to the receivers 200 and 250 of FIG. 1. Referring to FIG. 6, the sender 500 may include a clock generation block 510, an enable signal generation block 520, a sender count block 530, a heartbeat generation block 540, and a data sending block 550. The receiver 600 may include a receiver count block 610, an error detection block 620, and a data receiving block 630. Each block of the sender 500 and the receiver 600 may be individually implemented as a circuit.

In an embodiment, the enable signal generation block 520, the sender count block 530, and the heartbeat generation block 540 may constitute the first safety core logic SCL1 of FIG. 1 or may be included in the first safety core logic SCL1 of FIG. 1. In an embodiment, the receiver count block 610 and the error detection block 620 may constitute the second safety core logic SCL2 of FIG. 1 or may be included in the second safety core logic SCL2 of FIG. 1. In an embodiment, the data sending block 550 may constitute the first data transfer logic DTL1 of FIG. 1 or may be included in the first data transfer logic DTL1 of FIG. 1. The data receiving block 630 may constitute the second data transfer logic DTL2 of FIG. 1 or may be included in the second data transfer logic DTL2 of FIG. 1.

The clock generation block 510 may generate the clock signal CLK. The clock signal CLK may be a signal used for the operations of the sender 500 and the receiver 600. The clock generation block 510 may be identical or similar to the clock generation block 110 of FIG. 2 or the clock generation block 310 of FIG. 4, and may operate identically or similarly to the operation of the clock generation block 110 of FIG. 2 or the clock generation block 310 of FIG. 4. In an embodiment, the clock generation block 510 may transmit the generated clock signal CLK to a plurality of blocks. For example, the clock generation block 510 may transmit the clock signal CLK to the sender count block 530 or the data sending block 550 of the sender 500. As another example, the clock generation block 510 may transmit the clock signal CLK to the receiver count block 610 or the data receiving block 630 through a 21st signal pin SP21, a 21st signal line SIG21, and a 22nd signal pin SP22. In FIG. 6, the sender 500 is illustrated and described as including the clock generation block 510, but it should be understood that the present disclosure is not limited thereto. An embodiment in which the clock generation block 510 is placed outside the sender 500 is also within the scope of the present disclosure.

The enable signal generation block 520 may generate the enable signal EN. In an embodiment, the enable signal generation block 520 may generate the enable signal EN in response to a data transfer start. For example, the enable signal generation block 520 may generate the enable signal EN, which maintains the first level during the period of the clock signal CLK in response to the data transfer start. The length of the enable signal EN is just an example and it may be shorter or longer than the period of the clock signal CLK.

In an embodiment, the enable signal generation block 520 may transition the state of the enable signal EN in response to the data transfer start. For example, the enable signal generation block 520 may normally maintain the enable signal EN at logic LOW, and may transition the enable signal EN to logic HIGH in response to the data transfer start. The enable signal generation block 520 may generate the enable signal EN identical or similar to the count enable blocks 120 and 320 of FIG. 2 and FIG. 4.

In an embodiment, the enable signal generation block 520 may further generate a parity enable signal. For example, the enable signal generation block 520 may further generate a parity enable signal the same as the enable signal EN. As another example, the enable signal generation block 520 may further generate a parity enable signal having a level inverted to the level of the enable signal EN. The parity enable signal may be identical or similar to the parity enable signal PEN of FIGS. 2 and 3. In an embodiment, the enable signal generation block 520 may deliver a parity enable signal to the error detection block 620 of the receiver 600 through separate signal points and a signal line.

The enable signal generation block 520 may deliver the generated enable signal EN to a plurality of blocks. For example, the enable signal generation block 520 may transmit the enable signal EN to the sender count block 530 or the data sending block 550. As another example, the enable signal generation block 520 may transmit the enable signal EN to the receiver count block 610 or the data receiving block 630 through a 23rd signal pin SP23, a 22nd signal line SIG22, and a 24th signal pin SP24. The blocks that receive the enable signal EN may perform functions respectively corresponding to the blocks in response to the level of the enable signal EN.

The sender count block 530 may change, update, or manage the sending count value SCV of the sender 500. In an embodiment, the sender count block 530 may change or update the sending count value SCV in response to the enable signal EN and the clock signal CLK. The sender count block 530 may be identical or similar to the sender count blocks 130 and 330 of FIGS. 2 and 4, and may operate identically or similarly to the operations of the sender count blocks 130 and 330 of FIGS. 2 and 4.

In an embodiment, the sender count block 530 may change, update, or manage the sending count value SCV by using a circular counter. For example, when the sending count value SCV reaches its maximum, the sender count block 530 may reset it to the minimum value. For a more detailed example, if the sending count value SCV is represented in 3 bits and the sending count value SCV before the update is “111”, the next sending count value SCV may be “000”.

The sender count block 530 may deliver the sending count value SCV to other blocks. For example, the sender count block 530 may deliver the sending count value SCV to the heartbeat generation block 540.

The heartbeat generation block 540 may generate the heartbeat signal HB. In an embodiment, the heartbeat generation block 540 may generate the heartbeat signal HB depending on the sending count value SCV received from the sender count block 530. For example, the heartbeat generation block 340 may generate the heartbeat signal HB when the sending count value SCV reaches its maximum value. In this case, the heartbeat signal HB may have a second level (e.g., logic HIGH) for the duration of the clock signal CLK period.

The heartbeat generation block 540 may be identical or similar to the heartbeat generation block 340 of FIG. 4. The heartbeat generation block 540 may operate identically or similarly to an operation of the heartbeat generation block 340 of FIG. 4. In an embodiment, the heartbeat generation block 540 may deliver the generated heartbeat signal HB to another block. For example, the heartbeat generation block 540 may deliver the generated heartbeat signal HB to the error detection block 620 through a 25th signal pin SP25, a 23rd signal line SIG23, and a 26th signal pin SP26.

FIG. 6 illustrates that the heartbeat generation block 540 receives the sending count value SCV and generates the heartbeat signal HB upon detecting that the sending count value SCV has reached its maximum value, but the scope of the present disclosure is not limited thereto. In an embodiment, the heartbeat generation block 540 may receive the enable signal EN and the clock signal CLK, and may accumulate the received enable signal EN. When the level of the accumulated enable signal EN is equal to a threshold value, the heartbeat signal HB may be generated.

The data sending block 550 may transmit the data DATA in response to the clock signal CLK and the enable signal EN. In an embodiment, the data DATA transmitted by the data sending block 550 may be data received from the outside of the sender 500. For example, the data DATA transmitted by the data sending block 550 may be data received from the processor 1110 of FIG. 1 or the buffer 1120 of FIG. 1.

In an embodiment, the data sending block 550 may transmit the data DATA through one or more signal lines. For example, the data sending block 550 may transmit the data DATA to the data receiving block 630 of the receiver 600 via a 24th signal line SIG24, which includes a plurality of signal lines. As another example, the data sending block 550 may transmit the data DATA to the data receiving block 630 through the 24th signal line SIG24, which includes one signal line. In this case, the data DATA of the data sending block 550 may be obtained by converting parallel data into serial data through a serializer-deserializer (SERDES). The data sending block 550 may be similar to the data sending block 140 of FIG. 1 and may operate similarly to the operation of the data sending block 140 of FIG. 1.

The receiver count block 610 may change, update, or manage the receiving count value RCV of the receiver 600. In an embodiment, the receiver count block 610 may change or update the receiving count value RCV in response to the enable signal EN and the clock signal CLK. In an embodiment, the receiver count block 610 may be identical or similar to the receiver count blocks 210 and 410 of FIGS. 2 and 4, and may operate identically or similarly to the operations of the receiver count blocks 210 and 410 of FIGS. 2 and 4.

In an embodiment, the receiver count block 610 may change, update, or manage the receiving count value RCV by using a circular counter. For example, when the receiving count value RCV reaches its maximum, the receiver count block 610 may reset it to the minimum value. For a more detailed example, if the receiving count value RCV is represented in 3 bits and the receiving count value RCV before the update is “111”, the next receiving count value RCV may be “000”.

In an embodiment, when no error occurs in communication between the sender 500 and the receiver 600, the sending count value SCV of the sender count block 530 may be the same as the receiving count value RCV of the receiver count block 610. The receiver count block 610 may deliver the receiving count value RCV to other blocks. For example, the receiver count block 610 may deliver the receiving count value RCV to the error detection block 620.

The error detection block 620 may detect an error in communication between the sender 500 and the receiver 600. For example, the error detection block 620 may detect an error due to the loss of the clock signal CLK received by the receiver 600, or an error due to the loss of the enable signal EN received by the receiver 600. In an embodiment, the error detection block 620 may detect whether a communication error occurs, based on the heartbeat signal HB and the receiving count value RCV. For example, if the error detection block 620 receives the heartbeat signal HB while the receiving count value RCV is not at its maximum value (or alternatively, at its minimum value or any predefined value), the error detection block 420 may detect a communication error. As another example, when the error detection block 620 does not receive the heartbeat signal HB while the receiving count value RCV is at its maximum value (or alternatively, at its minimum value or any predefined value), the error detection block 420 may detect a communication error.

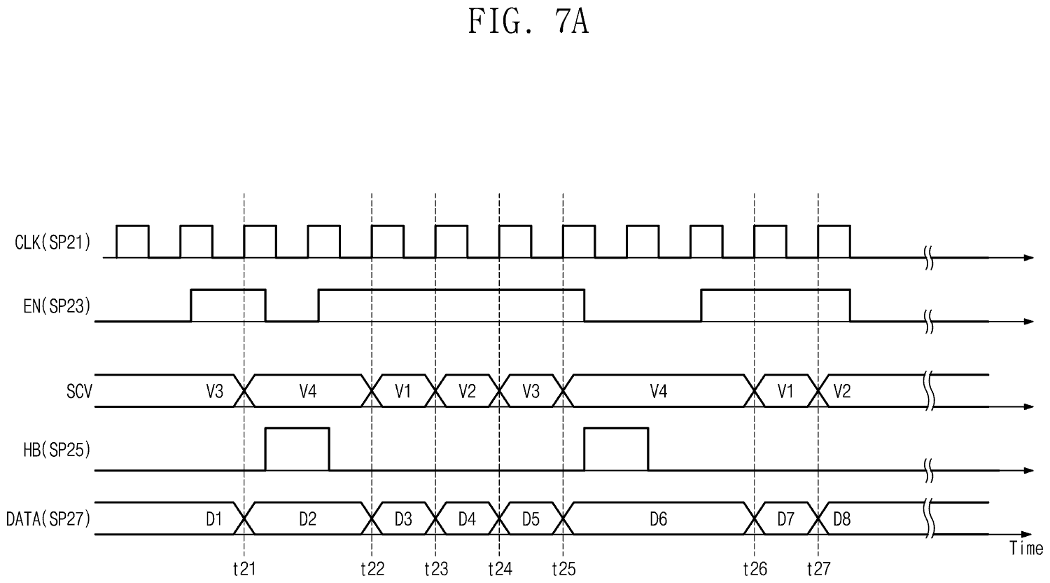

In an embodiment, in response to the clock signal CLK, the error detection block 620 may generate an error signal or may transition the level of the error signal. For example, upon detecting a communication error, the error detection block 620 may generate an error signal or transition the level of the error signal in response to the rising edge of the clock signal CLK immediately after detection. In an embodiment, the error detection block 620 may detect an error caused by the loss of the clock signal CLK (or the enable signal EN) based on the heartbeat signal HB. The error detection of the clock signal CLK of the error detection block 620 will be described in more detail with reference to FIG. 7B.

The data receiving block 630 may receive the data DATA transmitted by the data sending block 550. In an embodiment, the data receiving block 630 may process, sense, capture, or extract received data in response to the clock signal CLK and the enable signal EN. For example, the data receiving block 630 may capture or extract the data DATA from a signal, which is received through the 28th signal pin SP28, based on the clock signal CLK.

The data receiving block 630 may deliver the captured or extracted data DATA to other components (e.g., the processor 1210 or the buffer 1220) of the second electronic device 1200 of FIG. 1 including the receiver 600. The data receiving block 630 may be similar to the data receiving block 230 of FIG. 2 and may operate similarly to the operation of the data receiving block 230 of FIG. 2.

In FIG. 6, an embodiment in which the sender count block 530 updates the sending count value SCV based on the sender count block 530 increasing the sending count value SCV is described, but the scope of the present disclosure is not limited thereto. It should also be understood that an embodiment, in which the sender count block 530 updates the sending count value SCV based on the sender count block 530 decreasing the sending count value SCV, is within the scope of the present disclosure. In FIG. 6, an embodiment in which the receiver count block 610 updates the receiving count value RCV based on the receiver count block 610 increasing the receiving count value RCV is described, but the scope of the present disclosure is not limited thereto. An embodiment in which the receiver count block 610 updates the receiving count value RCV based on the receiver count block 610 decreasing the receiving count value RCV should be understood to fall within the scope of the present disclosure. In FIG. 6, an embodiment in which the sender count block 530 updates the sending count value SCV by 1 is described as an example, but it should be understood that an embodiment in which the sender count block 530 updates the sending count value SCV by another value is also within the scope of the present disclosure. Likewise, an embodiment in which the receiver count block 610 updates the receiving count value RCV by 1 is described. However, it should be understood that an embodiment, in which the receiver count block 610 updates the receiving count value RCV by another value, is also within the scope of the present disclosure.

FIG. 7A is a timing diagram showing an example of an operation of the sender of FIG. 6, according to an embodiment of the present disclosure. FIG. 7B is a timing diagram showing an example of an operation of the receiver of FIG. 6, according to an embodiment of the present disclosure. An example of communication error detection between the sender 500 and the receiver 600 according to an embodiment of the present disclosure is described with reference to FIGS. 1, 6, 7A, and 7B. A horizontal axis of FIGS. 7A and 7B may indicate time, and a vertical axis thereof may indicate the level or value of a signal.

Referring to FIG. 7A, changes of the clock signal CLK of the sender 500, the enable signal EN of the sender 500, the sending count value SCV, the heartbeat signal HB of the sender 500, and the data DATA transmitted by the sender 500 are illustrated over time. Referring to FIG. 6 together, the level of the clock signal CLK of the sender 500 may be the signal level of the 21st signal pin SP21. Since the clock signal CLK periodically has a rising edge, the level of the clock signal CLK of the sender 500 may periodically have a rising edge.

The level of the enable signal EN of the sender 500 may be the signal level of the 23rd signal pin SP23. The enable signal EN may have a logic HIGH level in response to a start of data transfer. The sending count value SCV may be changed or updated in response to the enable signal EN and the clock signal CLK. For example, the sending count value SCV may be a value of a circular counter, and may initially have the third value V3.

At a 21st time point t21, the sending count value SCV may be changed to the fourth value V4, which is the next value, in response to the rising edge of the clock signal CLK and the signal level of the 23rd signal pin SP23 being logic HIGH. Likewise, the sending count value SCV may change to the first value V1, which is a minimum value, at a 22nd time point t22, and may sequentially have the second value V2, the third value V3, and the fourth value V4 from a 23rd time point t23 to a 25th time point t25. At a 26th time point t26 and a 27th time point t27, the sending count value SCV may be respectively changed to the first value V1 and the second value V2 in response to the signal level of the 23rd signal time point SP23 being logic HIGH and the clock signal CLK being at the rising edge.

The level of the heartbeat signal HB of the sender 500 may be the signal level of the 25th signal pin SP25. In an embodiment, the signal level of the heartbeat signal HB may be changed to logic HIGH in response to the sending count value SCV being the maximum value. For example, the level of the heartbeat signal HB of the sender 500 may transition to logic HIGH after (or immediately after) the 21st time point t21 in response to the sending count value SCV having the fourth value V4 at the 21st time point t21. Likewise, the level of the heartbeat signal HB of the sender 500 may transition to logic HIGH after (or immediately after) the 25th time point t25 in response to the sending count value SCV having the fourth value V4 at the 25th time point t25. In an embodiment, the duration for which the heartbeat signal HB of the sender 500 remains at logic HIGH may corresponds to the period of the clock signal CLK, but the scope of the present disclosure is not limited thereto.

In FIG. 7A, it is described that the sending count value SCV increases, but the scope of the present disclosure is not limited thereto. It should be understood that an embodiment in which the sending count value SCV sequentially decreases is also within the scope of the present disclosure. In this case, the signal level of the heartbeat signal HB may transition to logic HIGH in response to the sending count value SCV having the minimum value.

The data DATA transmitted by the sender 500 may correspond to the signal level of the 27th signal pin SP27. For example, the data initially transmitted by sender 500 may be first data D1. The data sending block 550 may change data, which is to be transmitted, to the next data in response to the level of the enable signal EN being logic HIGH and the clock signal CLK being at a rising edge. For example, from the 21st time point t21 to the 27th time point t27, the data sending block 550 may sequentially change the data to be transmitted, respectively, to the second to eighth data D2 to D8.

Referring to FIG. 7B, changes of the clock signal CLK of the receiver 600, the enable signal EN of the receiver 600, the receiving count value RCV, the heartbeat signal HB of the receiver 600, reception data RD, and the error signal ERR are illustrated over time. Referring to FIG. 6 together, the clock signal CLK of the receiver 600 may be the clock signal CLK received by the receiver 600, and the level of the clock signal CLK of the receiver 600 may be the signal level of the 22nd signal pin SP22. For example, the level of the clock signal CLK of the receiver 600 may not have a rising edge at a 35th time point t35. In other words, some of the clock signal CLK received by the receiver 600 may be lost.

The enable signal EN of the receiver 600 may be the enable signal EN received by the receiver, and the level of the enable signal EN of the receiver 600 may be the signal level of the 24th signal pin SP24. For example, the waveform of the enable signal EN of the receiver 600 may be identical to the waveform of the enable signal EN of the sender 500 in FIG. 7A.

Like the sending count value SCV of FIG. 7A, the receiving count value RCV may be updated in response to the enable signal EN and the rising edge of the clock signal CLK. In an embodiment, the receiving count value RCV may be a value of a circular counter of the receiver count block 610. For example, the receiving count value RCV may initially have the third value V3. At the 31st time point t31, the receiving count value RCV may be changed or updated to the fourth value V4 in response to the clock signal CLK of the receiver 600 having a rising edge and the level of the 24th signal pin SP24 being logic HIGH.

From the 32nd time point t32 to the 34th time point t34, the receiving count value RCV may be changed or updated identically to the sending count value SCV of FIG. 7A. In other words, at the 32nd time point t32, the receiving count value RCV may be changed to the first value V1, which is the minimum value, again. At the 33rd time point t33 and the 34th time point t34, the receiving count value RCV may be sequentially changed or updated to the second value V2 and the third value V3.

Unlike the sending count value SCV at the 25th time point t25 of FIG. 7A, the receiving count value RCV may not be changed or updated at the 35th time point t35. This is because the level of the 22nd signal pin SP22 (i.e., the level of the clock signal CLK) does not have a rising edge. At a 36th time point t36 and a 37th time point t37, the receiving count value RCV may be respectively updated to the fourth value V4 and the first value V1 in response to the clock signal CLK having a rising edge and the level of the enable signal EN being logic HIGH.

The heartbeat signal HB of the receiver 600 may be the heartbeat signal HB received by the receiver 600, and the level of the heartbeat signal HB of the receiver 600 may be the level of the 26th signal pin SP26. The waveform of the heartbeat signal HB of the receiver 600 may be identical to the waveform of the heartbeat signal HB of the sender 500 of FIG. 7A. The reception data RD may be generated as the data receiving block 630 detects the transmitted data DATA of the sender 500 received through the 27th signal pin SP27, the 24th signal line SIG24, and a 28th signal pin SP28.

In an embodiment, the reception data RD may be captured or sensed by the data receiving block 630 in response to the level of the enable signal EN being logic HIGH and the clock signal CLK being at a rising edge. For example, the reception data RD detected initially may be the first data D1 of FIG. 7A, and data detected from the 31st time point t31 to the 34th time point t34 may be the second to fifth data D2 to D5 sequentially. Unlike the transmission data (i.e., the signal corresponding to the 27th signal pin SP27) in FIG. 7A, which changes to the sixth data D6 at the 35th time point t35, the reception data RD may remain unchanged at the 35th time point t35, retaining the fifth data D5. This is because the clock signal CLK does not have a rising edge at the 35th time point t35.

At the 36th time point t36 and the 37th time point t37, the reception data RD may be changed to the seventh data D7 and the eighth data D8, respectively. That is, due to the loss of the clock signal CLK at the 35th time point t35, a portion of the transmitted data (i.e., the sixth data D6) from the sender 500 may be lost, resulting in a communication error between the sender 500 and the receiver 600.

The error signal ERR may be a signal generated by the error detection block 620. The error detection block 620 may generate the error signal ERR based on the heartbeat signal HB and the receiving count value RCV. The error detection block 620 may generate the error signal ERR in response to the rising edge of the clock signal CLK. Accordingly, after (or immediately after) the 31st time point t31, since the level of the heartbeat signal HB is logic HIGH and the receiving count value RCV has the fourth value V4, which is the maximum value, the level of the heartbeat signal HB may be maintained at logic LOW. On the other hand, at the 35th time point t35, the heartbeat signal HB is at logic HIGH, but the receiving count value RCV remains at the third value V3. This discrepancy may indicate a communication error, causing the error signal ERR to transition or update to logic HIGH (e.g., at the 36th time point t36). That is, a communication error due to the loss of the rising edge of the clock signal CLK at the 35th time point t35 may be detected.

In FIG. 7B, it is described that the receiving count value RCV increases, but the scope of the present disclosure is not limited thereto. It should be understood that an embodiment in which the receiving count value RCV sequentially decreases is also within the scope of the present disclosure. In this case, if the receiving count value RCV is not at its minimum value when the heartbeat signal HB is at logic HIGH, the error detection block 620 may detect a communication error.

An embodiment, in which both the sending count value SCV and the receiving count value RCV are changed to increase or decrease, is described, but the scope of the present disclosure is not limited thereto. For example, an embodiment, in which the sending count value SCV is changed to increase and the receiving count value RCV is changed to decrease, and an embodiment in which the sending count value SCV is changed to decrease and the receiving count value RCV is changed to increase may also be within the scope of the present disclosure. In this case, the sending count value SCV or the receiving count value RCV may have an appropriate initial value to detect a communication error based on a comparison with the heartbeat signal HB.

The sender 500 and the receiver 600 as described with reference to FIGS. 6, 7A, and 7B may detect communication errors caused by signal loss. 1. If an error occurs in the transmission or reception of the clock signal CLK, the receiver 600 may detect the communication error using an operation identical or similar to that described with reference to FIGS. 7A and 7B. 2. If an error occurs in the transmission or reception of the enable signal EN, the receiver 600 may detect the communication error using an operation identical or similar to that described with reference to FIGS. 7A and 7B. Alternatively, it may detect the error using a parity enable signal, as described with reference to FIGS. 2 and 3. 3. If an error occurs in the transmission or reception of the heartbeat signal HB, the receiver 600 may detect a communication error based on the absence of the heartbeat signal HB when the receiving count value RCV is at its maximum (or minimum) value. 4. If an error occurs in the transmission or reception of the data DATA, the receiver 600 or an electronic device including the receiver 600 (e.g., the second electronic device 1200 in FIG. 1) may detect and correct the error using ECC encoding or ECC decoding. The sender 500 and the receiver 600 described with reference to FIGS. 6, 7A, and 7B may detect a communication error caused by the loss of the clock signal CLK, the loss of the enable signal EN, or the loss of the data DATA, which may occur due to changes in dynamic voltage frequency scaling (DVFS) or variations in operating environments.

In an embodiment, the receiver 600 may provide an electronic device (e.g., the second electronic device 1200 of FIG. 1) including the receiver 600 with a notification that a communication error occurs. In an embodiment, an electronic device (e.g., the second electronic device 1200 of FIG. 1) may request another electronic device (e.g., the first electronic device 1100) to re-transmit data corresponding to the heartbeat signal HB, in which an error is detected, and data subsequent to data corresponding to the heartbeat signal HB, in which an error is detected, through a sender (e.g., the sender 150).

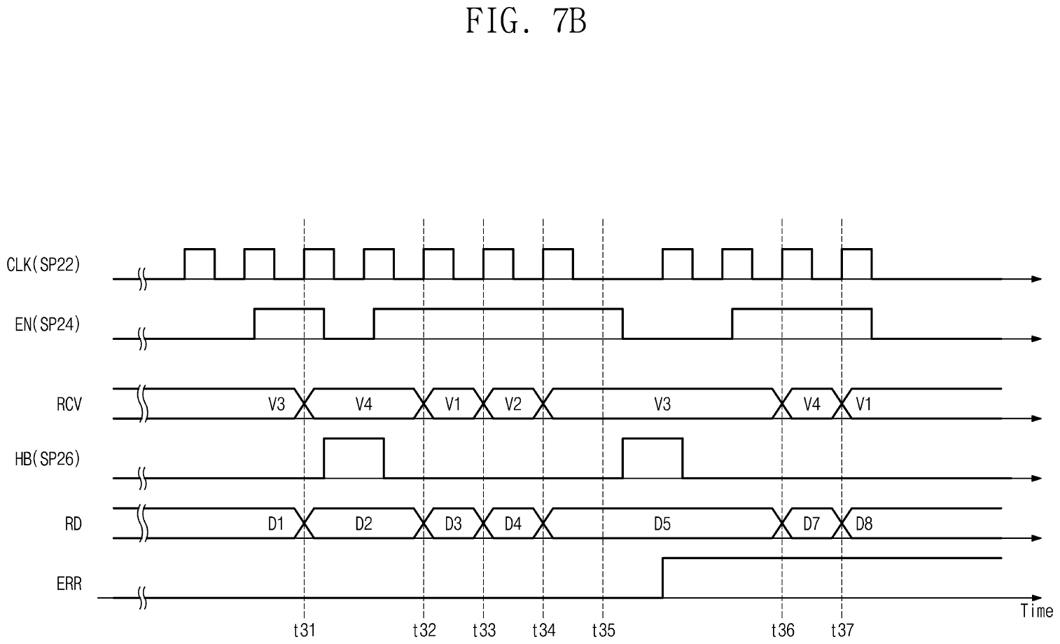

FIG. 8 is a flowchart showing an example of an operating method of the receiver of FIG. 6, according to an embodiment of the present disclosure. A communication error detection operating method of the receiver 600 of FIG. 6 according to an embodiment of the present disclosure is described with reference to FIGS. 1 to 8.

In operation S110, the receiver 600 may receive the clock signal CLK, the data DATA, and the enable signal EN. For example, referring to FIG. 6 together, the receiver 600 may receive the clock signal CLK from the sender 500 through the 22nd signal pin SP22, and may receive the enable signal EN from the sender 500 through the 24th signal pin SP24. As another example, the receiver 600 may receive the data DATA from the sender 500 through the 28th signal pin SP28.

In operation S120, the receiver 600 may update the receiving count value RCV of the receiver count block 610. In an embodiment, the receiver 600 may update the receiving count value RCV in response to the enable signal EN and the clock signal CLK. In an embodiment, the receiver 600 may update the receiving count value RCV through the receiver count block 610. For example, the receiver 600 may update the receiving count value RCV through the receiver count block 610 in response to the level of the enable signal EN being logic HIGH and the clock signal CLK being at the rising edge.

In an embodiment, the receiving count value RCV may be a value of a circular counter that is managed, changed, or updated by the receiver count block 610. For example, when the receiving count value RCV has a maximum value, the next updated value may be the minimum value of the receiving count value RCV. In an embodiment, the receiver count block 610 may update the receiving count value RCV by increasing the receiving count value RCV. For example, the receiver count block 610 may update the receiving count value RCV in response to the clock signal CLK and the enable signal EN, and may update the receiving count value RCV to the minimum value of receiving count value RCV when the receiving count value RCV reaches its maximum value.

In FIG. 8, an embodiment, in which the receiving count value RCV is updated based on increasing the receiving count value RCV, is described, but the scope of the present disclosure is not limited thereto. It should be understood that an embodiment in which the receiving count value RCV is updated based on decreasing the receiving count value RCV is also within the scope of the present disclosure. The receiver 600 may process received data simultaneously with operation S120. For example, the receiver 600 may process or capture the received data DATA through the data receiving block 630 in response to the enable signal EN and the rising edge of the clock signal CLK.

In operation S130, the next operation may be determined based on whether the heartbeat signal HB is received by the receiver 600. When the heartbeat signal HB is not received, the receiver 600 may return to operation S110. Conversely, when the heartbeat signal HB is received, the receiver 600 may proceed to operation S140. When the receiver 600 returns to operation S110 in operation S130, the receiver 600 may operation S110 and operation S120 again.

In operation S140, the receiver 600 may determine the next operation based on whether the receiving count value RCV is equal to a predetermined value. In an embodiment, the predetermined value may be the maximum value (or the minimum value) of the receiving count value RCV. In an embodiment, when the heartbeat signal HB is received, the receiver 600 may determine whether the receiving count value RCV is equal to the predetermined value, through the error detection block 620.

When the receiving count value RCV is equal to the predetermined value in operation S140, the receiver 600 may terminate an operation. When the receiving count value RCV is not equal to the predetermined value in operation S140, the receiver 600 may proceed to operation S150. In operation S150, the receiver 600 may generate an error signal indicating that a communication error occurs. For example, the receiver 600 may indicate that a communication error occurs, through the error detection block 620.

After operation S150, the receiver 600 may terminate its operation. In FIG. 8, after operation S140 or operation S150, the receiver 600 may return to operation S110 instead of terminating its operation. The operations of FIG. 8 are described as being performed sequentially, but the scope of the present disclosure is not limited thereto. It should be understood that an embodiment, in which the order of operations is changed, or an embodiment in which at least some of operations are performed to be overlapped are also within the scope of the present disclosure. For example, operation S110 may be performed simultaneously with performing operation S140.

The receiver 600 may detect errors occurring during the process of receiving data from the sender 500 based on the operation described in FIG. 8. Specifically, the receiver 600 may detect errors in receiving the enable signal EN or the clock signal CLK using the heartbeat signal HB. Additionally, the receiver 600 or an electronic device (e.g., the second electronic device 1200 in FIG. 1) including the receiver 600 may correct data errors based on ECC encoding and decoding when an error in data occurs.

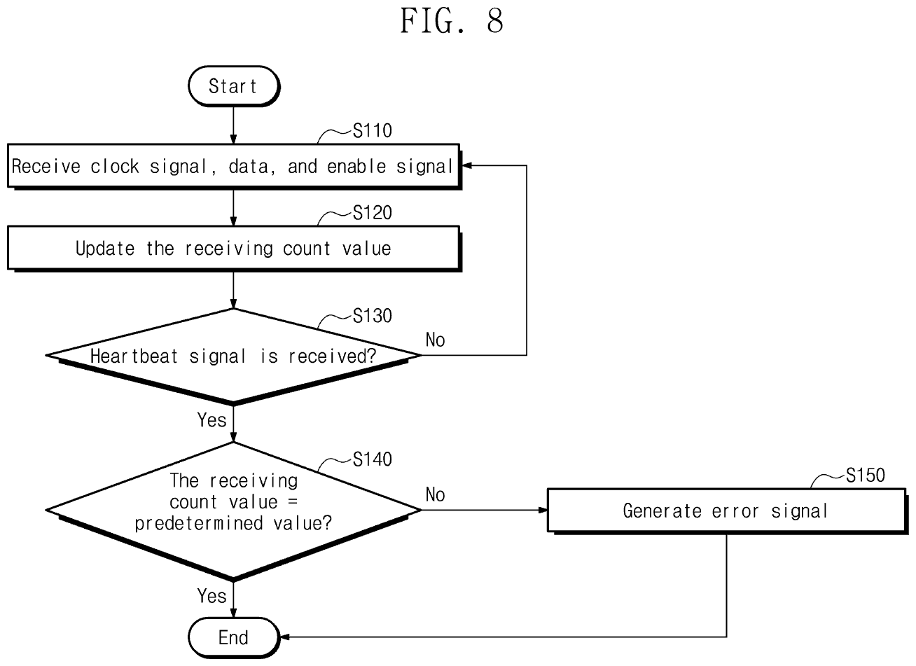

FIG. 9 is a block diagram showing in detail the receiver count block of FIG. 6, according to an embodiment of the present disclosure. Referring to FIG. 9, the receiver count block 610 may include a register circuit 611, an adder circuit 613, and a selection circuit 615. The receiver count block 610 according to an embodiment of the present disclosure is described in detail with reference to FIG. 9.

The register circuit 611 may store a receiving count value RCV. In an embodiment, the register circuit 611 may change or update the receiving count value RCV based on the clock signal CLK. For example, the register circuit 611 may store an input value in response to the rising edge of the clock signal CLK.

In an embodiment, the register circuit 611 may include one or more flip-flops. For example, the register circuit 611 may include a number of flip-flops equal to the number of digits in the receiving count value RCV, with each flip-flop operating in response to the clock signal CLK. In an embodiment, the register circuit 611 may provide the adder circuit 613 or the first input of the selection circuit 615 with the stored receiving count value RCV.

The adder circuit 613 may change the receiving count value RCV. In an embodiment, the adder circuit 613 may increase the receiving count value RCV by an arbitrary value. For example, the adder circuit 613 may increase the receiving count value RCV by 1. In an embodiment, the adder circuit 613 may decrease the receiving count value RCV by an arbitrary value. For example, the adder circuit 613 may decrease the receiving count value RCV by 1.

In an embodiment, the adder circuit 613 may have an equal number input bits and output bits. For example, the adder circuit 613 may receive a 3-bit input, may add 1, and then may receive a 3-bit output. In an embodiment, the receiving count value RCV may be unsigned bits. For example, the receiving count value RCV may have 3 unsigned bits, indicating values from 0 (i.e., 000) to 7 (i.e., 111).

In an embodiment, when the adder circuit 613 receives the receiving count value RCV at its minimum value as an input, the adder circuit 613 may output the minimum value of the receiving count value RCV. For example, if the receiving count value RCV is represented using 3 unsigned bits and the adder circuit 613 receives “111,” the adder circuit 613 may generate “000” by adding 1, effectively resetting the count and outputting the minimum value of the receiving count value RCV. (This is equivalent to removing the overflow of the most significant bit.)

In FIG. 9, an embodiment in which the adder circuit 613 increases the receiving count value RCV by 1 is described, but the scope of the present disclosure is not limited thereto. For example, when the adder circuit 613 has a 3-bit input/output and decreases the receiving count value RCV by 1, the adder circuit 613 may decrease the receiving count value RCV by adding 111 (i.e., 2's complement of 1) to a value received as an input. In this case, when receiving the minimum value (e.g., 000) as an input, the adder circuit 613 may output the maximum value (e.g., 111) based on the above operation.

In FIG. 9, it is described that the adder circuit 613 increases or decreases the receiving count value RCV by 1. However, it should be understood that an embodiment of changing the receiving count value RCV by a value other than 1 is also within the scope of the present disclosure. The adder circuit 613 may provide an output value to the selection circuit 615. For example, the adder circuit 613 may provide an output value to a second input of the selection circuit 615.

The selection circuit 615 may select one of a plurality of inputs and may output the selected one. For example, the selection circuit 615 may select either a first input or the second input and may output the selected one. In an embodiment, the selection circuit 615 may determine an output in response to the level of the enable signal EN. The selection circuit 615 may provide the output to an input of the register circuit 611.

For example, when the level of the enable signal EN is HIGH(1), the selection circuit 615 may deliver the output of the adder circuit 613 to the register circuit 611. As another example, when the level of the enable signal EN is LOW(0), the selection circuit 615 may deliver the output of the register circuit 611 to the register circuit 611. In an embodiment, the selection circuit 615 may include one or more multiplexers that determine the output in response to the enable signal EN. For example, the selection circuit 615 may include a number of multiplexers equal to the number of digits of the receiving count value RCV. As a more detailed example, when the receiving count value RCV has 3 bits, the selection circuit 615 may include three multiplexers that operate in response to the enable signal EN.

In FIG. 9, like the receiver count block 610 included in the receiver 600, the receiver count blocks 210 and 410 of FIG. 2 and FIG. 4 may be identical or similar to the receiver count block 610 of FIG. 9. Likewise, the sender count blocks 130, 330, and 530 of the senders 100, 300, and 500 of FIGS. 2, 4, and 6 may be identical or similar to the receiver count block 610 of FIG. 9.

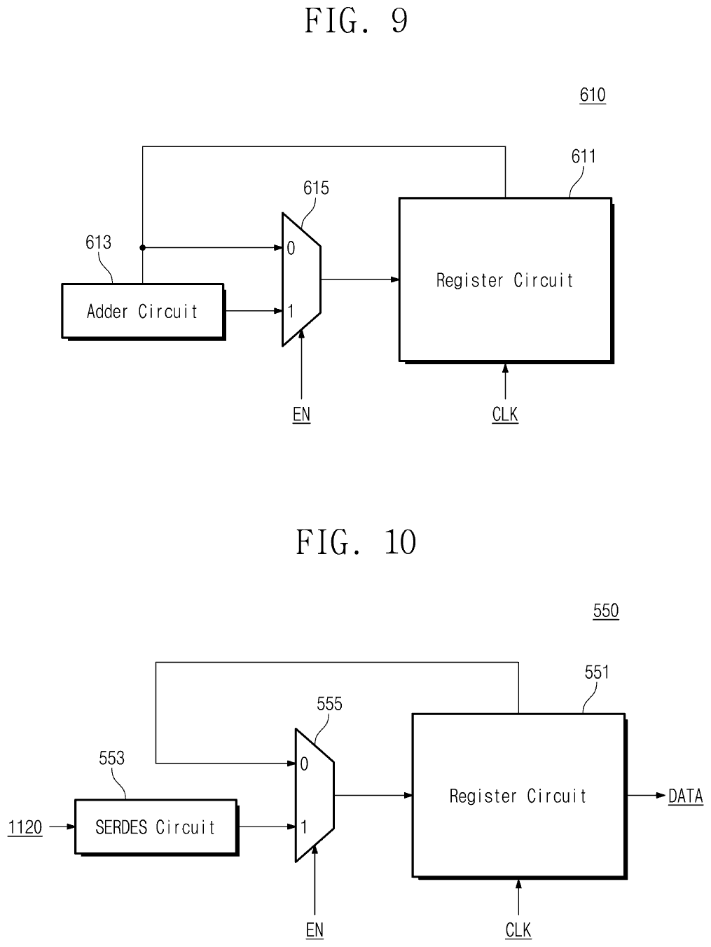

FIG. 10 is a block diagram showing in detail the data sending block of the sender of FIG. 6, according to an embodiment of the present disclosure. Referring to FIG. 10, the data sending block 550 may include a register circuit 551, a SERDES circuit 553, and a selection circuit 555. In FIG. 10, an embodiment, in which the data sending block 550 includes a SERDES circuit, is illustrated, but it should be understood that an embodiment in which the data sending block 550 does not include the SERDES circuit 553 is also within the scope of the present disclosure.

The register circuit 551 may temporarily store the data DATA to be transmitted. In an embodiment, the register circuit 551 may operate in response to the clock signal CLK. The register circuit 551 may be identical or similar to the register circuit 611 of FIG. 9, and may operate identically or similarly to the operation of the register circuit 611 of FIG. 9.

In an embodiment, the register circuit 551 may include one or more flip-flops that operate in response to the clock signal CLK. For example, the register circuit 551 may include a number of flip-flops equal to the number of bits in the data DATA to be transmitted at one time. For a more detailed example, if the data sending block 550 does not include the SERDES circuit 553, the register circuit 551 may contain flip-flops corresponding to the length (or number of bits) of the data DATA. The register circuit 551 may either transmit the data DATA to the receiver 600 through signal points or provide the data DATA to the selection circuit 555. For example, the register circuit 551 may provide the stored data DATA to a first input of the selection circuit 555.

The SERDES circuit 553 may serialize parallel data. For example, the SERDES circuit 553 may receive a plurality of bits, convert the plurality of bits into serial data, and output the serial data sequentially. The SERDES circuit 553 may provide the output to a second input of the selection circuit 555. In an embodiment, the SERDES circuit 553 may receive data from the outside. For example, the SERDES circuit 553 may receive data from the buffer 1120 of FIG. 1. Although the SERDES circuit 553 is described as receiving data from the buffer 1120, the SERDES circuit 553 may receive data from the processor 1110 of FIG. 1, or may receive data generated through an operation when the electronic device is a SoC.

When the data sending block 550 does not include the SERDES circuit 553, the data may be provided directly to the second input of the selection circuit 555. For example, if the data sending block 550 does not include the SERDES circuit 553, the second input of the selection circuit 555 may receive data (i.e., newly transmitted data) from the buffer 1120, the processor 1110, or an electronic device (e.g., the first electronic device 1100).

The selection circuit 555 may select one of a plurality of inputs. In an embodiment, the selection circuit 555 may select one of the plurality of inputs in response to the enable signal EN. In an embodiment, the selection circuit 555 may deliver its output to the register circuit 551. For example, when the enable signal EN is HIGH(1), the selection circuit 555 may deliver the second input (i.e., new data) to the register circuit 551. On the other hand, when the enable signal EN is LOW(0), the selection circuit 555 may deliver the first input (i.e., the existing data) to the register circuit 551.

In an embodiment, the selection circuit 555 may include one or more multiplexers. For example, when the data sending block 550 includes the SERDES circuit 553, the selection circuit 555 may include a multiplexer. (This is because the SERDES circuit 553 outputs data sequentially, one bit at a time.)

As another example, when the data sending block 550 does not include the SERDES circuit 553, the selection circuit 555 may include one or more multiplexers. For a more detailed example, the selection circuit 555 may include a number of multiplexers corresponding to the length (or number of bits) of the data DATA. In other words, the number of flip-flops in the register circuit 551 may be the same as the number of multiplexers in the selection circuit 555. The selection circuit 555 may be identical or similar to the selection circuit 615 of FIG. 9, and may operate identically or similarly to the operation of the selection circuit 615 of FIG. 9.

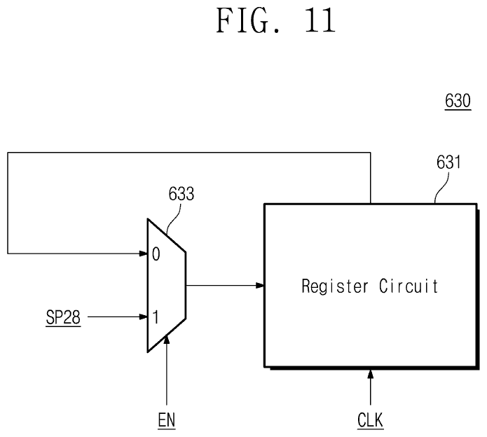

FIG. 11 is a block diagram showing in detail the data receiving block of FIG. 6, according to an embodiment of the present disclosure. Referring to FIG. 11, the data receiving block 630 may include a register circuit 631 and a selection circuit 633.

The register circuit 631 may store data in response to the clock signal CLK. In an embodiment, the register circuit 631 may transmit stored data to the outside of the receiver 600. For example, the register circuit 631 may deliver the stored data to a processor (e.g., the processor 1210 of the second electronic device 1200 of FIG. 1), a buffer (the buffer 1220 of the second electronic device 1200 of FIG. 1), or an electronic device (e.g., the second electronic device 1200 of FIG. 1). The register circuit 631 may provide the stored data to the first input of the selection circuit 633.

In an embodiment, the register circuit 631 may include one or more flip-flops that operate in response to the clock signal CLK. In an embodiment, the number of flip-flops included in the register circuit 631 may correspond to the length (or number of bits) of the data received by the data receiving block 630. For example, when the data received by the data receiving block 630 has the length of 3 bits, the register circuit 631 may include three flip-flops that operate in response to the clock signal CLK.

The selection circuit 633 may select one of a plurality of inputs and may output the selected input. The second input of the selection circuit 633 may be data received by the data receiving block 630. For example, referring to FIG. 6, the selection circuit 633 may be connected to the 28th signal pin SP28 and may receive the data DATA transmitted by the data sending block 550.

The selection circuit 633 may deliver an output to the register circuit 631. In an embodiment, the selection circuit 633 may select one of a plurality of inputs in response to the enable signal EN. For example, when the enable signal EN is HIGH(1), the selection circuit 633 may deliver the data received from the 28th signal pin SP28 to the register circuit 631. As another example, when the enable signal EN is LOW (0), the selection circuit 633 may deliver the output (e.g., the existing output) of the register circuit 631 to the register circuit 631.

In an embodiment, the selection circuit 633 may include one or more multiplexers operating in response to the clock signal CLK. In an embodiment, the number of multiplexers in the selection circuit 633 may correspond to the length (or number of bits) of data received at one time. For example, if the data receiving block 630 receives data in 3-bit segments, the selection circuit 633 may include three multiplexers.

The data receiving block 630 may process, detect, or capture received data based on the structure of FIG. 11. For example, referring to FIG. 6 together with FIG. 11, the data receiving block 630 may process, detect, or capture data transmitted by the data sending block 550 and received through the 27th signal pin SP27, the 24th signal line SIG24, and the 28th signal pin SP28.

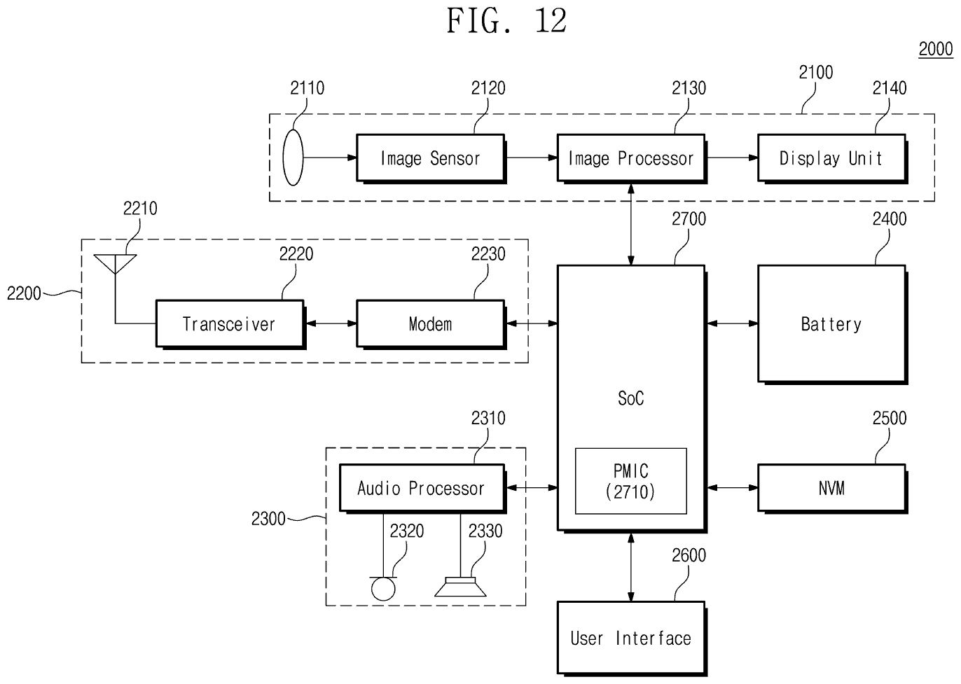

FIG. 12 is a block diagram showing an electronic device 2000, according to an embodiment of the present disclosure. Referring to FIG. 12, the electronic device 2000 according to an embodiment of the present disclosure includes an image processing unit 2100, a wireless transceiver unit 2200, an audio processing unit 2300, a battery 2400, a nonvolatile memory device 2500, a user interface 2600, and a SoC 2700. The electronic device 200 may operate under the control of the SoC 2700 (hereinafter also referred to as a “controller”).

The image processing unit 2100 may include a lens 2110, an image sensor 2120, an image processor 2130, and a display unit 2140. The image processor 2130 may convert real-world images into image data through the lens 2110 and the image sensor 2120. The display unit 2140 may display image data signals generated by the image processor 2130 or image data provided to a user. The display unit 2140 may be composed of a liquid crystal display (LCD) or organic light emitting diodes (OLED). When the LCD or OLED is implemented as a touch screen, the display unit 2140 may also operate together with the user interface 2600.

The wireless transceiver unit 2200 includes an antenna 2210, a transceiver 2220, and a modulator/demodulator (modem) 2230. The wireless transceiver unit 2200 may perform wireless communication functions. The transceiver 2220 may adjust the frequency of a signal transmitted through the antenna 2210 or amplify the signal, and may adjust the frequency of a signal received through the antenna 2210 or amplify the signal. The modem 2230 may include a sender that encodes and modulates a signal to be transmitted, and a receiver that demodulates and decodes a signal received through the antenna 2210. The antenna 2210 and the modem 2230 of the wireless transceiver unit 2200 may process signals exchanged with the external device/system in compliance with at least one of various wireless communication protocols, such as: long term evolution (LTE), worldwide interoperability for microwave access (WiMax), global system for mobile communication (GSM), code division multiple access (CDMA), Bluetooth, near field communication (NFC), wireless fidelity (Wi-Fi), and radio frequency identification (RFID).

The audio processing unit 2300 includes an audio processor 2310, a microphone 2320, and a speaker 2330. The audio processing unit 2300 may configure a codec, and the codec may include a data codec and an audio codec. The data codec may process packet data, etc., and the audio codec may process audio signals such as voice and multimedia files. Furthermore, the audio processing unit 2300 may perform a function of converting a digital audio signal received from the modem 2230 into an analog signal through an audio codec and playing the digital audio signal, or converting an analog audio signal generated from the microphone 2320 into a digital audio signal through an audio codec and transmitting the digital audio signal to the modem 2230. The codec may be provided separately or included in the controller 2700.

The battery 2400 may provide the power required to operate the electronic device 2000. In FIG. 12, the electronic device 2000 is depicted as receiving power from the battery 2400. However, it should be understood that an embodiment in which an external power source supplements or replaces the battery 2400 is also within the scope of the present disclosure. The nonvolatile memory device 2500 may store the data of the electronic device 2000. For example, the nonvolatile memory device 2500 may be or include a NAND flash memory device. The nonvolatile memory device 2500 may be implemented with a memory card (e.g., a MMC, an eMMC, a SD card, or a micro SD card) and the like according to an embodiment of the present disclosure.

The user interface 2600 may receive an input from an external source or may generate an output to the external source. For example, the user interface 2600 may receive an input through a device such as a keyboard, a mouse, or the like. In an embodiment, the user interface 2600 may include a driver for receiving inputs from devices. In an embodiment, the user interface 2600 may generate an output by operating in conjunction with the display unit 2140 or the audio processing unit 2300.

The SoC 2700 may drive an application program, an operating system, or the like. In an embodiment, the SoC 2700 may include a processor, such as a general-purpose processor or a special-purpose processor. In an embodiment, the SoC 2700 may control components of the electronic device 2000. The SoC 2700 may include a PMIC 2710. The PMIC 2710 receives a voltage from the battery 2400 and may convert the level of the supplied voltage. The PMIC 2710 may provide the converted voltage level to each component of the electronic device 2000.

In an embodiment, communication between the SoC 2700 and other components may be performed based on the sender, the receiver, and operations thereof described with reference to FIGS. 1 to 10. For example, the SoC 2700 may transmit data to or receive data from the modem 2230 based on the operations of the sender and the receiver described with reference to FIGS. 1 to 11. As another example, the SoC 2700 may exchange data with the image processor 2130 based on the operations of the sender and the receiver described with reference to FIGS. 1 to 11. In an embodiment, the SoC 2700 may detect errors when communicating with other components based on the sender, the receiver, and operations thereof described with reference to FIGS. 1 to 10.

The components of the electronic device 2000 illustrated in FIG. 12 are just examples and the scope of the present disclosure is not limited thereto. For example, the electronic device 2000 may further include a volatile memory device as system memory, and the volatile memory device may operate under the control of the SoC 2700. In an embodiment, the electronic device 2000 may not include some of the components of FIG. 12. For example, the electronic device 2000 may not include the image processing unit 2100.

The signal pin SP referenced throughout the detailed description is provided for convenience and should not be construed as limiting the scope of the present disclosure. In an embodiment, the signal pin SP may represent a conceptual configuration. Alternatively, in another embodiment, the signal pin SP may correspond to a physical structure, such as a pad or a pin used for communication between a sender and a receiver. Additionally, in an embodiment, blocks may be directly connected through a signal line. For example, referring to FIG. 2, the data sending block 140 may be directly connected to the data receiving block 230 through the fourth signal line SIG4.

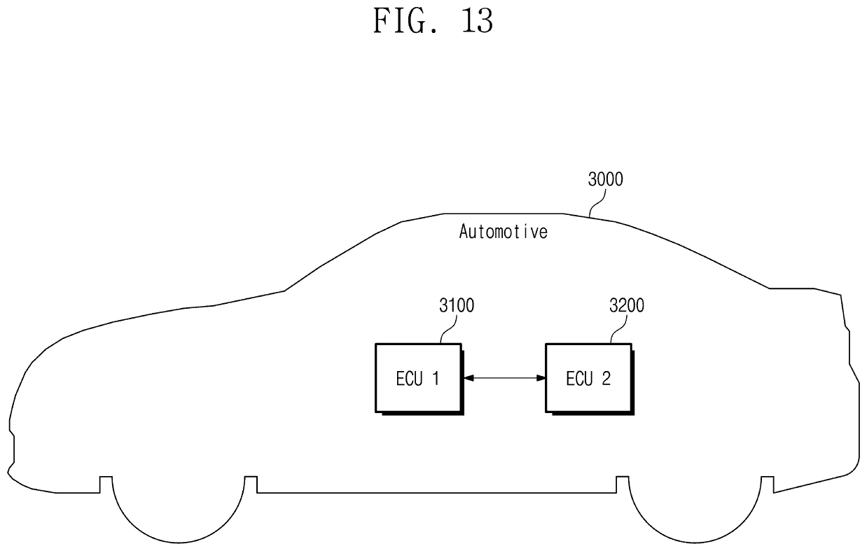

FIG. 13 is a drawing showing an automotive system 3000, according to an embodiment of the present disclosure. Referring to FIG. 13, the automotive system 3000 may include a first electronic control unit (ECU) 3100 and a second ECU 3200. The automotive system 3000 according to an embodiment of the present disclosure is described with reference to FIG. 9.

The automotive system 3000 may be a system that including an engine or motor, such as an automobile, and is configured to perform various operations. For example, the automotive system 3000 may be a system that may be included in various types of automobiles, such as passenger vehicles, commercial vehicles, military vehicles, or special purpose vehicles, and may allow a vehicle to perform various operations.

The first ECU 3100 and the second ECU 3200 may control the operation of the automotive system 3000. In an embodiment, the first ECU 3100 and the second ECU 3200 may operate independently and may perform different functions. For example, the first ECU 3100 may control the acceleration of the vehicle, and the second ECU 3200 may control the deceleration of the vehicle or control brake lights. For example, each of the first ECU 3100 and the second ECU 3200 may be an engine control unit (ECU), a panel controller, a transmission control unit (TCU), a powertrain control module (PCM), an electronic stability control (ESC), an airbag controller, a tire pressure monitoring system (TPMS), an anti-lock braking system (ABS), or the like, may include at least some thereof, or perform an operation similar thereto.

In an embodiment, the communication between the first ECU 3100 and the second ECU 3200 may be performed based on the operations described with reference to FIGS. 1 to 11. For example, when the first ECU 3100 transmits the data DATA and the clock signal CLK to the second ECU 3200, the first ECU 3100 may transmit a heartbeat signal depending on the sending count value as described with reference to FIGS. 4 to 11. Here, the second ECU 3200 may detect an error in communication by comparing the heartbeat signal and a receiving count value as described with reference to FIGS. 4 to 11. On the basis of performing communication operations described with reference to FIGS. 1 to 11, the first ECU 3100 and the second ECU 3200 may perform stable communication and have a safety class according to a higher standard.

The first ECU 3100 and the second ECU 3200 may comply with standards related to vehicle specifications. In an embodiment, the first ECU 3100 and the second ECU 3200 may have a safety class according to a specific standard. For example, the first ECU 3100 and the second ECU 3200 may have one of the following safety classes or standards: automotive safety integrity level (ASIL) D, ASIL C, ASIL B, ASIL A, or quality management (QM). In ASIL classification, ASIL D represents the highest required safety level. The safety level may be sequentially lowered in the order of ASIL C, ASIL B, and ASIL A.

The automotive system 3000 in FIG. 13 is illustrated as including the first ECU 3100 and the second ECU 3200. However, the scope of the present disclosure is not limited thereto. In an embodiment, the automotive system 3000 may further include additional ECUs or function units, or memory devices. In an embodiment, the automotive system 3000 may further include a storage device or a memory device with a designated safety class. For example, the automotive system 3000 may include a storage or memory device that stores data for the first ECU 3100 and complies with a safety class standard.

Throughout the detailed description, an embodiment in which the blocks or circuits operating in response to the clock signal CLK operate in response to a rising edge is described, but the scope of the present disclosure is not limited thereto. In an embodiment, the blocks or circuits of FIGS. 1 to 11 may operate in response to the falling edge of the clock signal CLK. In an embodiment, some of the blocks or circuits of FIGS. 1 to 11 may operate in response to a rising edge of the clock signal CLK, and other some of the blocks or circuits of FIGS. 1 to 11 may operate in response to a falling edge of the clock signal CLK.

As used throughout the detailed description, components described with reference to the terms “logic”, “block”, “˜er or ˜or”, etc. and function blocks illustrated in the drawings can be implemented with software, hardware, or a combination thereof. For example, the software may be a machine code, firmware, an embedded code, and application software. For example, the hardware may include an electrical circuit, an electronic circuit (an analog circuit or a digital circuit), a processor, a computer, an integrated circuit, integrated circuit cores, a pressure sensor, an inertial sensor, a microelectromechanical system (MEMS), a passive element, or a combination thereof.

The above description refers to detailed embodiments for carrying out the present disclosure. The present disclosure may include embodiments with simple design modifications or those that can be easily adapted. Additionally, technologies that can be readily modified and implemented based on the described embodiments are also within the scope of the present disclosure.

According to an embodiment of the present disclosure, a sender and a receiver are provided that can indicate the occurrence of a communication error when a clock signal is lost or experiences an error. Additionally, an operating method for the sender and receiver, and an electronic device including the same are also disclosed.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electronic system comprising:
a first electronic device including a sender that is configured to transmit data; and
a second electronic device including a receiver that is configured to receive the data,
wherein the sender is configured to:
transmit a clock signal, an enable signal, and a heartbeat signal to the receiver;
update a sending count value in response to the clock signal and the enable signal; and
generate the heartbeat signal when the sending count value is a first value, and
wherein the receiver is configured to:
update a receiving count value in response to the clock signal and the enable signal; and
generate an error signal when the receiving count value does not have the first value upon receipt of the heartbeat signal.

2. The electronic system of claim 1, wherein the sender includes:
an enable signal generation circuit configured to generate the enable signal; and
a sender count circuit configured to manage the sending count value.

3. The electronic system of claim 2, wherein the sender further includes:
a heartbeat generation circuit configured to generate the heartbeat signal based on the sending count value.

4. The electronic system of claim 3, wherein the sending count value is a value of a circular counter, and
wherein the first value is a maximum value of the sending count value.

5. The electronic system of claim 1, wherein the receiver includes:
a receiver count circuit configured to update the receiving count value; and
an error detection circuit configured to receive the heartbeat signal and the receiving count value, and to generate the error signal in response to the clock signal.

6. The electronic system of claim 5, wherein the receiver count circuit includes:
a register circuit configured to store the receiving count value;
an adder circuit configured to generate a third value by adding a second value to the receiving count value; and
a selection circuit configured to receive an output of the register circuit as a first input, receive the third value as a second input, and to output the first input or the second input in response to the enable signal.

7. The electronic system of claim 5, wherein the receiver further includes:
a data receiving circuit configured to operate in response to the clock signal and the enable signal and to receive the data.

8. The electronic system of claim 7, wherein the data receiving circuit captures the data in response to the enable signal being at a ‘HIGH’ level and the clock signal being at a rising edge.

9. The electronic system of claim 7, wherein the data receiving circuit includes:
a register circuit configured to capture the data in response to the clock signal; and
a selection circuit configured to receive an output of the register circuit as a first input, receive the data as a second input, and output the first input or the second input in response to the enable signal.

10. The electronic system of claim 9, wherein the selection circuit outputs the second input in response to the enable signal being at a ‘HIGH’ level, and
wherein the selection circuit delivers an output to the register circuit.

11. A receiver for receiving data, the receiver comprising:
a receiver count circuit configured to receive a clock signal and an enable signal and to update a receiving count value; and
an error detection circuit configured to receive a heartbeat signal and the receiving count value, and to generate an error signal in response to the clock signal,
wherein the error detection circuit generates the error signal when the receiving count value is not equal to a first value upon receipt of the heartbeat signal.

12. The receiver of claim 11, wherein the receiver count circuit updates the receiving count value in response to the enable signal and the clock signal.

13. The receiver of claim 12, wherein the receiver count circuit manages a circular counter, and
wherein the receiving count value is a value of the circular counter.

14. The receiver of claim 12, wherein the error detection circuit generates the error signal in response to a rising edge of the clock signal.

15. The receiver of claim 12, further comprising:
a data receiving circuit configured to operate in response to the clock signal and the enable signal and to receive the data.

16. The receiver of claim 15, wherein the receiver count circuit includes:
a register circuit configured to store the receiving count value;
an adder circuit configured to generate a third value by adding a second value to the receiving count value; and
a selection circuit configured to receive an output of the register circuit as a first input, receive the third value as a second input, and output the first input or the second input in response to the enable signal.

17. The receiver of claim 16, wherein the data receiving circuit captures the data in response to the enable signal being at a ‘HIGH’ level and the clock signal being at a rising edge.

18. The receiver of claim 16, wherein the data receiving circuit includes:
a register circuit configured to capture the data in response to the clock signal; and
a selection circuit configured to receive an output of the register circuit as a first input, receive the data as a second input, and output the first input or the second input in response to the enable signal.

19. The receiver of claim 12, wherein the data is transmitted by a sender, and
wherein the receiver receives the clock signal, the enable signal, and the heartbeat signal from the sender.

20. An operating method of a receiver for receiving data, the method comprising:
receiving a clock signal, an enable signal, and the data;
updating a receiving count value in response to the enable signal and the clock signal;
receiving a heartbeat signal, and determining whether the receiving count value is a first value, when the heartbeat signal is received; and
generating an error signal when the receiving count value is not the first value.
